(19) United States
(12) Patent Application Publication
(10) Pub. No.: US 2026/0033131 A1
(43) Pub. Date: Jan. 29, 2026

(54) ORGANIC LIGHT-EMITTING DEVICE

(71) Applicant: CANON KABUSHIKI KAISHA, Tokyo (JP)

(72) Inventors: SATORU SHIOBARA, Kanagawa (JP); YOSUKE NISHIDE, Kanagawa (JP); ITARU TAKAYA, Kanagawa (JP); HITOSHI NAGASHIMA, Kanagawa (JP); CHIEKO MIHARA, Kanagawa (JP)

(21) Appl. No.: 19/349,853

(22) Filed: Oct. 3, 2025

Related U.S. Application Data
(63) Continuation of application No. PCT/JP2024/014988, filed on Apr. 15, 2024.

(30) Foreign Application Priority Data
Apr. 17, 2023 (JP) 2023-067176
Mar. 28, 2024 (JP) 2024-053580

(51) Int. Cl. H10K 50/16; H10K 50/19; H10K 85/30; H10K 85/60

(52) U.S. Cl. CPC H10K 50/16; H10K 50/19; H10K 85/324; H10K 85/342; H10K 85/622; H10K 85/623; H10K 85/624; H10K 85/626; H10K 85/633; H10K 85/636; H10K 85/654; H10K 85/656; H10K 85/6572; H10K 85/6574; H10K 85/6576; H10K 85/658

(57) ABSTRACT

The present disclosure provides an organic light-emitting device including, in this order, a first electrode, a first light-emitting layer, a charge transport layer, a charge generation region including a charge generation layer and an intermediate layer, a second light-emitting layer, and a second electrode, in which the charge generation layer contains a metal atom, the intermediate layer is disposed between the charge generation layer and the second light-emitting layer, and the intermediate layer contains a fused polycyclic hydrocarbon compound.

### CROSS-REFERENCE TO RELATED APPLICATIONS

This application is a Continuation of International Patent Application No. PCT/JP2024/014988, filed Apr. 15, 2024, which claims the benefit of Japanese Patent Application No. 2023-067176, filed Apr. 17, 2023, and Japanese Patent Application No. 2024-053580, filed Mar. 28, 2024, all of which are hereby incorporated by reference herein in their entirety.

### BACKGROUND

### Field of the Technology

The present disclosure relates to an organic light-emitting device.

### Description of the Related Art

An organic electroluminescent device (hereinafter, also referred to as an “organic EL device” or an “organic light-emitting device”) is a device that emits light by energizing an organic compound layer that includes an anode, a cathode, and a light-emitting layer disposed between these electrodes.

In recent years, in addition to single-color organic light-emitting devices that emit white light by incorporating red, green, and blue light-emitting materials into a single light-emitting layer, stacked organic light-emitting devices have been developed in which separate light-emitting layers for red, green, and blue are stacked. Compared to single-layer organic light-emitting devices, stacked organic light-emitting devices tend to require higher driving voltages, and thus structures incorporating charge generation regions are known. Charge generation regions, however, can be more prone to degradation than other organic layers. Degradation of charge generation regions leads to higher operating voltages, reduced efficiency, and lower durability. Therefore, there is a demand for the development of stable charge generation regions.

U.S. Patent Application Publication No. 2016/0204360 and Japanese Patent Laid-Open No. 2016-122666 each disclose a configuration in which a stacked organic light-emitting device includes a charge generation region composed of a heterocyclic compound and a metal complex.

However, since the charge generation region is composed of the heterocyclic compound and the metal complex, the n-dopant contained in the charge generation region easily diffuses. Therefore, the stacked organic light-emitting devices disclosed in U.S. Patent Application Publication No. 2016/0204360 and Japanese Patent Laid-Open No. 2016-122666 have room for improvement in durability.

### SUMMARY

The present disclosure has been made in view of the above problems, and the present disclosure is directed to providing an organic light-emitting device having excellent durability.

An organic light-emitting device according to the present disclosure includes, in this order, a first electrode, a first light-emitting layer, a charge transport layer, a charge generation region including a charge generation layer and an intermediate layer, a second light-emitting layer, and a second electrode, in which the charge generation layer contains a metal atom, the intermediate layer is disposed between the charge generation layer and the second light-emitting layer, and the intermediate layer contains a fused polycyclic hydrocarbon compound.

Features of the present disclosure will become apparent from the following description of embodiments with reference to the attached drawings.

### BRIEF DESCRIPTION OF THE DRAWINGS

FIG. 1 is a schematic cross-sectional view illustrating an example of an organic light-emitting device according to an embodiment of the present disclosure.

FIG. 2A is a schematic cross-sectional view illustrating an example of a pixel of a display apparatus according to an embodiment of the present disclosure.

FIG. 2B is a schematic cross-sectional view of an example of a display apparatus including organic light-emitting devices according to an embodiment of the present disclosure.

FIG. 3 is a schematic view of an example of a display apparatus according to an embodiment of the present disclosure.

FIG. 4A is a schematic view of an example of an image pickup apparatus according to an embodiment of the present disclosure.

FIG. 4B is a schematic view of an example of an electronic apparatus according to an embodiment of the present disclosure.

FIG. 5A is a schematic view of an example of a display apparatus according to an embodiment of the present disclosure.

FIG. 5B is a schematic view of an example of a foldable display apparatus.

FIG. 6A is a schematic view of an example of a lighting apparatus according to an embodiment of the present disclosure.

FIG. 6B is a schematic view of an example of an automobile including an automotive lighting unit according to an embodiment of the present disclosure.

FIG. 7A is a schematic view illustrating an example of a wearable device according to an embodiment of the present disclosure.

FIG. 7B is a schematic view of an example of a wearable device according to an embodiment of the present disclosure, the wearable device including an image pickup apparatus.

FIG. 8A is a schematic view of an example of an image-forming apparatus according to an embodiment of the present disclosure.

FIG. 8B is a schematic view of an example of an exposure light source of an image-forming apparatus according to an embodiment of the present disclosure.

FIG. 8C is a schematic view of an example of an exposure light source of an image-forming apparatus according to an embodiment of the present disclosure.

FIG. 9 illustrates the emission spectra of Example 1 and Comparative Example 1.

FIG. 10 illustrates the results of the driving test for Example 1 and Comparative Example 1.

### DESCRIPTION OF THE EMBODIMENTS

In this specification, examples of a halogen atom include, but are not limited to, a fluorine atom, a chlorine atom, a bromine atom, and an iodine atom. Among these, a fluorine atom is preferred.

Examples of an alkali metal atom include, but are not limited to, a lithium atom, a sodium atom, a potassium atom, a rubidium atom, and a cesium atom. Among these, a lithium atom or a cesium atom is preferred.

Examples of an alkaline-earth metal atom include, but are not limited to, a beryllium atom, a magnesium atom, a calcium atom, and a strontium atom.

As an alkyl group, an alkyl group having 1 or more and 20 or less carbon atoms may be used. Specific examples include, but are not limited to, a methyl group, an ethyl group, a n-propyl group, an isopropyl group, a n-butyl group, an isobutyl group, a sec-butyl group, a tert-butyl group, a n-pentyl group, an isopentyl group, a tert-pentyl group, a neopentyl group, a n-hexyl group, an octyl group, a cyclohexyl group, a 1-adamantyl group, and a 2-adamantyl group. The alkyl group preferably has 1 or more and 10 or less carbon atoms, more preferably 1 or more and 6 or less carbon atoms. Specifically, a methyl group or a tert-butyl group is preferred.

As an alkoxy group, an alkoxy group having 1 or more and 10 or less carbon atoms may be used. Specific examples thereof include, but are not limited to, a methoxy group, an ethoxy group, a n-propoxy group, an isopropoxy group, a n-butoxy group, a tert-butoxy group, a 2-ethyl-octyloxy group, and a benzyloxy group. The alkoxy group preferably has 1 or more and 4 or less carbon atoms. Specifically, a methoxy group is preferred.

As an aryl group, an aryl group having 6 or more and 30 or less carbon atoms may be used. Specific examples thereof include, but are not limited to, a phenyl group, a naphthyl group, a phenanthryl group, an anthryl group, a fluorenyl group, a biphenylenyl group, an acenaphthylenyl group, a chrysenyl group, a pyrenyl group, a triphenylenyl group, a picenyl group, a fluoranthenyl group, a perylenyl group, a naphthacenyl group, a terphenyl group, a phenylene group, a naphthylene group, a phenanthrenylene group, a biphenyl group, a fluoranthenylene group, a chrysenylene group, and a pyrenylene group.

As a heterocyclic group, a heterocyclic group having 3 to 27 carbon atoms is preferred. Specific examples thereof include, but are not limited to, a thienyl group, a pyrrolyl group, a pyrazinyl group, a pyridyl group, an indolyl group, a quinolyl group, an isoquinolyl group, a naphthyridinyl group, an acridinyl group, a phenanthrolinyl group, a carbazolyl group, a benzo[a]carbazolyl group, a benzo[b]carbazolyl group, a benzo[c]carbazolyl group, a phenazinyl group, a phenoxazinyl group, a phenothiazinyl group, a benzothiophenyl group, a dibenzothiophenyl group, a benzofuranyl group, a dibenzofuranyl group, an oxazolyl group, and an oxadiazolyl group.

Specific examples of a silyl group include, but are not limited to, a trimethylsilyl group and a triphenylsilyl group.

Specific examples of an amino group include, but are not limited to, an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-tert-butylphenyl)amino group, and an N-phenyl-N-(4-trifluoromethylphenyl)amino group. The amino group is preferably an N,N-dimethylamino group or an N,N-diphenylamino group.

Examples of substituents that may be further contained in the alkyl group, the alkoxy group, the aryl group, the heterocyclic group, the silyl group, and the amino group include, but are not limited to, alkyl groups, such as a methyl group, an ethyl group, a n-propyl group, an isopropyl group, a n-butyl group, an isobutyl group, a sec-butyl group, a tert-butyl group, a n-pentyl group, an isopentyl group, a tert-pentyl group, a neopentyl group, a n-hexyl group, and a cyclohexyl group; alkoxy groups, such as a methoxy group, an ethoxy group, an isopropoxy group, a n-butoxy group, and a tert-butoxy group; substituted amino groups, such as an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-tert-butylphenyl)amino group, and an N-phenyl-N-(4-trifluoromethylphenyl)amino group; aryl groups, such as a phenyl group, a naphthyl group, a phenanthryl group, an anthryl group, a fluorenyl group, a biphenylenyl group, an acenaphthylenyl group, a chrysenyl group, a pyrenyl group, a triphenylenyl group, a picenyl group, a fluoranthenyl group, a perylenyl group, a naphthacenyl group, a biphenyl group, and a terphenyl group; heteroaryl groups, such as a thienyl group, a pyrrolyl group, a pyrazinyl group, a pyridyl group, an indolyl group, a quinolyl group, an isoquinolyl group, a naphthyridinyl group, an acridinyl group, a phenanthrolinyl group, a carbazolyl group, a benzo[a]carbazolyl group, a benzo[b]carbazolyl group, a benzo[c]carbazolyl group, a phenazinyl group, a phenoxazinyl group, a phenothiazinyl group, a benzothiophenyl group, a dibenzothiophenyl group, a benzofuranyl group, a dibenzofuranyl group, an oxazolyl group, and an oxadiazolyl group; a cyano group; and a trifluoromethyl group.

The durability of an organic light-emitting device can be evaluated on the basis of the time it takes for the luminance to decrease. By comparing the time it takes for the luminance to decrease from the initial level to a certain level, it can be expressed that the longer this time is, the higher the durability.

### Organic Light-Emitting Device

An organic light-emitting device according to the present disclosure includes, in this order, a first electrode, a first light-emitting layer, a charge transport layer, a charge generation region including a charge generation layer and an intermediate layer, a second light-emitting layer, and a second electrode, in which the charge generation layer contains a metal atom, the intermediate layer is disposed between the charge generation layer and the second light-emitting layer, and the intermediate layer contains a fused polycyclic hydrocarbon compound.

The organic light-emitting device according to the present disclosure is what is called a tandem-type light-emitting device including the charge generation region and the first light-emitting layer and the second light-emitting layer sandwiching the charge generation region.

The organic light-emitting device according to the present embodiment may include a third light-emitting layer in addition to the first light-emitting layer and the second light-emitting layer. The third light-emitting layer may be provided between the first electrode and the first light-emitting layer, between the first light-emitting layer and the second light-emitting layer, or between the second light-emitting layer and the second electrode.

Here, the first electrode may be an anode, and the second electrode may be a cathode.

The organic light-emitting device according to the present embodiment may have a device configuration that can emit white light. Specifically, the first light-emitting layer may emit red and green light, and the second light-emitting layer may emit blue light. The first light-emitting layer, the second light-emitting layer, and the third light-emitting layer may emit red, green, and blue light, respectively.

The organic light-emitting device according to the present embodiment may have a device configuration that can emit light other than white light. Specifically, the first light-emitting layer and the second light-emitting layer may emit light of the same color. With such a device configuration, an organic light-emitting device with improved luminance can be produced.

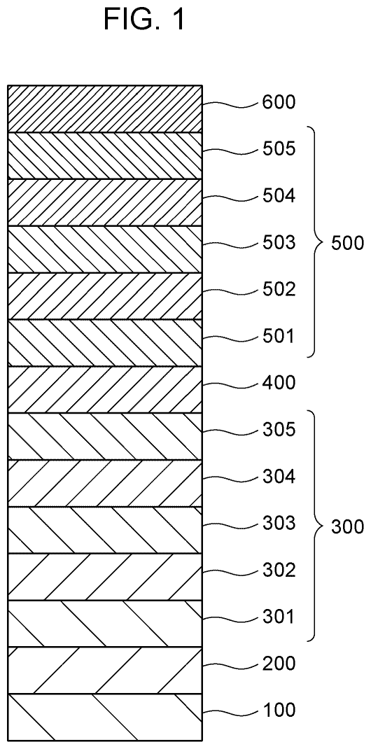

The present disclosure will be described in more detail below with reference to FIG. 1.

FIG. 1 is a schematic cross-sectional view of an organic light-emitting device according to an embodiment, in which a first electrode 200, a first light-emitting unit 300, a charge generation region 400, a second light-emitting unit 500, and a second electrode 600 are stacked in that order on a substrate 100.

In the organic light-emitting device according to the present disclosure, the first light-emitting unit 300 includes a first light-emitting layer 303 and a charge transport layer. Here, the charge transport layer may be a first electron transport layer 302 or a first hole transport layer 304. In the present disclosure, an embodiment in which the charge transport layer is the first electron transport layer 302 will be described below, but the present disclosure is not limited thereto. The charge transport layer is referred to as a hole transport layer when it is disposed between the light-emitting layer and the electrode that injects holes, and is referred to as an electron transport layer when it is disposed between the light-emitting layer and the electrode that injects electrons.

The first light-emitting layer 303 contains a first organic compound and a first light-emitting compound. For example, the first organic compound may be a host material, and the first light-emitting compound may be a guest material. The first light-emitting layer 303 may further contain an assist material or a guest material, if necessary. The first light-emitting unit 300 may include an organic compound layer other than the first light-emitting layer 303 and the charge transport layer. Specifically, the first light-emitting unit 300 may include a first hole injection layer 301, a first hole transport layer 302, a first electron injection layer 305, a hole-blocking layer, an electron-blocking layer, and the like.

In the organic light-emitting device according to the present disclosure, the second light-emitting unit 500 includes a second light-emitting layer 503. The second light-emitting layer 503 contains a second organic compound and a second light-emitting compound. The second organic compound may be a host material, and the second light-emitting compound may be a guest material. The second light-emitting layer 503 may further contain an assist material or a guest material, if necessary. The second light-emitting unit 500 may include an organic compound layer other than the second light-emitting layer 503. Specifically, it may include a second hole injection layer 501, a second hole transport layer 502, a second electron transport layer 504, a second electron injection layer 505, a hole-blocking layer, an electron-blocking layer, and the like.

Here, a host compound is a compound having the highest proportion by mass in compounds contained in each light-emitting layer. A guest compound is a compound that has a lower proportion by mass than the host in the compounds contained in the light-emitting layer and that is responsible for main light emission. An assist compound is a compound that has a lower proportion by mass than the host compound in the compounds contained in the light-emitting layer and that assists the light emission of the guest compound. The assist compound is also referred to as a second host compound.

In the organic light-emitting device according to the present disclosure, the charge generation region 400 includes the charge generation layer and the intermediate layer. The intermediate layer is provided between the charge generation layer and the second light-emitting layer 503 of the second light-emitting unit 500 and is a layer containing a fused polycyclic hydrocarbon compound and thus can inhibit the diffusion of metal atoms (a dopant, in particular, an n-type dopant) contained in the charge generation layer. The intermediate layer may be a layer different from the charge transport layer of the first light-emitting unit 300. The metal atoms contained in the charge generation layer are preferably, but not particularly limited to, alkali metal atoms, alkaline-earth metal atoms, or ytterbium atoms, more preferably lithium atoms, cesium atoms, or ytterbium atoms.

The intermediate layer may be a mixed layer of a fused polycyclic hydrocarbon compound and another material. When the intermediate layer contains a fused polycyclic hydrocarbon compound and a compound other than the fused polycyclic hydrocarbon compound, the fused polycyclic hydrocarbon compound contained in the intermediate layer is preferably contained in an amount of 25% or more by mass of the intermediate layer, more preferably 50% or more by mass, and still more preferably 75% or more by mass. Particularly preferably, the intermediate layer contains only the fused polycyclic hydrocarbon compound.

When the intermediate layer is a mixed layer of a fused polycyclic hydrocarbon compound and another material, the other material is preferably, but not particularly limited to, a compound having a phenanthroline skeleton or a fused polycyclic hydrocarbon compound different from the fused polycyclic hydrocarbon compound contained in the intermediate layer. More preferably, it is a compound having a plurality of phenanthroline skeletons or a fused polycyclic hydrocarbon compound different from the fused polycyclic hydrocarbon compound contained in the intermediate layer. Particularly preferably, it is a fused polycyclic hydrocarbon compound different from the fused polycyclic hydrocarbon compound contained in the intermediate layer.

Here, the fused polycyclic hydrocarbon compound refers to a compound that has a structure in which two or more ring structures are fused (aryl group other than benzene) and that is composed of a hydrocarbon. Specifically, the skeleton may be a naphthalene skeleton, a phenanthroline skeleton, an anthracene skeleton, a fluorene skeleton, an acenaphthylene skeleton, a chrysene skeleton, a pyrene skeleton, a triphenylene skeleton, a fluoranthene skeleton, a perylene skeleton, a biphenylene skeleton, a tetracene skeleton, or the like. The fused polycyclic hydrocarbon skeleton may further contain an alkyl group, an aralkyl group, an aryl group, or the like as a substituent. Specifically, it may be a methyl group, an ethyl group, an isobutyl group, a tert-butyl group, a phenyl group, a biphenyl group, a naphthyl group, a terphenyl group, a benzyl group, a phenylethyl group, or the like.

The intermediate layer is preferably adjacent to the charge generation layer. The charge generation layer may be adjacent to the charge transport layer of the first light-emitting unit 300.

When the charge generation layer of the charge generation region 400 is an n-type charge generation layer, the organic light-emitting device according to the present embodiment need not have the first electron injection layer 305. The reason for this is that in this case, the charge generation region 400 plays a role of injecting electrons into the first light-emitting unit 300. Since the first electron injection layer 305 is not provided, the total number of organic compound layers included in the organic light-emitting device according to the present embodiment can be reduced, thereby possibly leading to a reduction in the driving voltage of the organic light-emitting device.

In the organic light-emitting device according to the present embodiment, the charge generation region 400 may include an n-type charge generation layer and a p-type organic semiconductor layer. The n-type charge generation layer may contain an alkali metal atom or an alkaline-earth metal atom, preferably an alkali metal atom, and more preferably a lithium atom. An n-type organic semiconductor layer containing a compound having a lowest unoccupied molecular orbital (LUMO) energy level of −5.0 eV or less may be provided between the n-type charge generation layer and the p-type charge generation layer. This n-type organic semiconductor layer may contain, for example, a radialene compound or HAT-CN. The p-type organic semiconductor layer may also serve as a hole transport layer that transports holes to the second light-emitting layer. The same applies to the case where a charge generation region is provided between the second light-emitting layer and the third light-emitting layer.

The features of the organic light-emitting device according to the present disclosure will be described below.

(1) The organic light-emitting device according to the present disclosure is characterized in that the intermediate layer contains a fused polycyclic hydrocarbon compound, and the durability of the organic light-emitting device is improved by including the intermediate layer containing the fused polycyclic hydrocarbon compound. Fused polycyclic hydrocarbon compounds tend to have low polarity; thus, the diffusion of n-type dopants into the organic compound layers can be reduced. As a result, the deterioration of the organic compound layers due to the n-type dopant can be inhibited, and thus the organic light-emitting device according to the present disclosure has excellent durability. In contrast, the organic light-emitting devices described in Patent Literatures 1 and 2 are organic light-emitting devices in which each charge generation region is composed only of a heterocyclic compound and a metal complex. Compared with fused polycyclic hydrocarbon compounds, heterocyclic compounds tend to have higher polarity, and therefore the n-type dopant generated in the charge generation region is more likely to diffuse into the organic compound layer. Therefore, the organic light-emitting devices described in Patent Literatures 1 and 2 are organic light-emitting devices with low durability because the organic compound layers are easily degraded by the n-type dopant.

Therefore, the organic light-emitting device according to the present disclosure is an organic light-emitting device having excellent durability because the intermediate layer of the charge generation region contains the fused polycyclic hydrocarbon compound.

The organic light-emitting device according to the present disclosure preferably further has the following configuration. It is to be noted that only one of the following configurations may be satisfied, or multiple structures may be satisfied simultaneously.

(2) The fused polycyclic hydrocarbon compound has a skeleton having 10 or more carbon atoms.

(3) The charge transport layer or the charge generation layer contains a fused polycyclic hydrocarbon compound.

(4) The difference in LUMO energy levels between the fused polycyclic hydrocarbon compounds in the charge transport layer and the charge generation layer is small.

(5) The difference in HOMO energy levels between the fused polycyclic hydrocarbon compounds in the charge generation layer and the intermediate layer is small.

(6) The charge transport layer, the charge generation layer, and the intermediate layer each contain the same fused polycyclic hydrocarbon compound.

These configurations will be described below.

(2) The fused polycyclic hydrocarbon compound has a skeleton having 10 or more carbon atoms.

The fused polycyclic hydrocarbon compound contained in the organic light-emitting device according to the present embodiment preferably has a highly planar skeleton. This is because the highly planar skeleton facilitates intermolecular stacking, leading to the easy formation of denser layers. As a result, the diffusion of the n-type dopant can be further inhibited, and thus the organic light-emitting device according to the present embodiment has superior durability.

From the viewpoint of planarity, the fused polycyclic hydrocarbon compound preferably has a skeleton having 10 or more carbon atoms, more preferably has a skeleton in which four or more rings are fused. Specifically, the fused polycyclic hydrocarbon compound may be a compound containing naphthalene, fluorene, phenanthrene, triphenylene, anthracene, pyrene, chrysene, perylene, fluoranthene, or derivatives thereof. In consideration of stability, the fused polycyclic hydrocarbon compound may have a structure containing a combination of benzene, naphthalene, fluorene, phenanthrene, triphenylene, anthracene, pyrene, chrysene, perylene, and fluoranthene.

Organic compounds having lower molecular weights tend to exhibit superior sublimability; thus, a lower molecular weight is preferred. Therefore, the skeleton of the fused polycyclic hydrocarbon compound preferably has 30 or less carbon atoms, more preferably 20 or less carbon atoms. The fused polycyclic hydrocarbon compound may have 60 or less carbon atoms.

Particularly preferably, the fused polycyclic hydrocarbon compound has a bulky skeleton and a highly planar skeleton. When the fused polycyclic hydrocarbon compound has such a structure, highly planar skeletons tend to easily undergo intermolecular stacking, and the use of the bulky skeleton also tends to increase the glass transition temperature. As a result, the fused polycyclic hydrocarbon compound also has excellent thermal stability. Specifically, as the highly planar skeleton, it is preferable to have a skeleton composed of four or more rings, such as a pyrene skeleton, a triphenylene skeleton, or a chrysene skeleton. As the bulky skeleton, it is preferable to have a skeleton having a tert-butyl group or an isopropyl group, or a fluorene skeleton. More preferably, the fused polycyclic hydrocarbon compound has a pyrene skeleton and a fluorene skeleton.

The following are specific examples of fused polycyclic hydrocarbon compounds, but they are not limited to these.

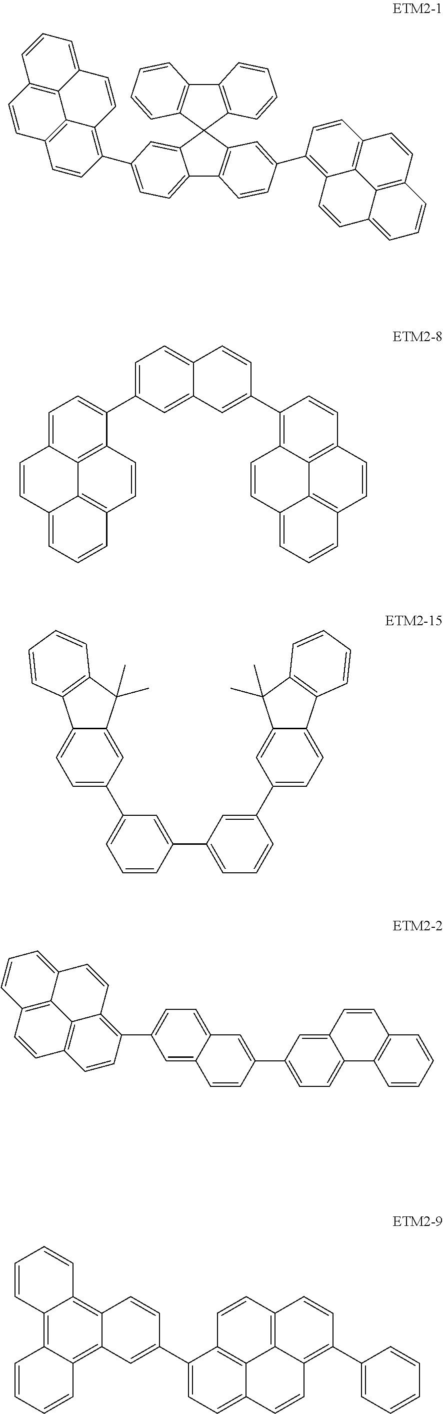

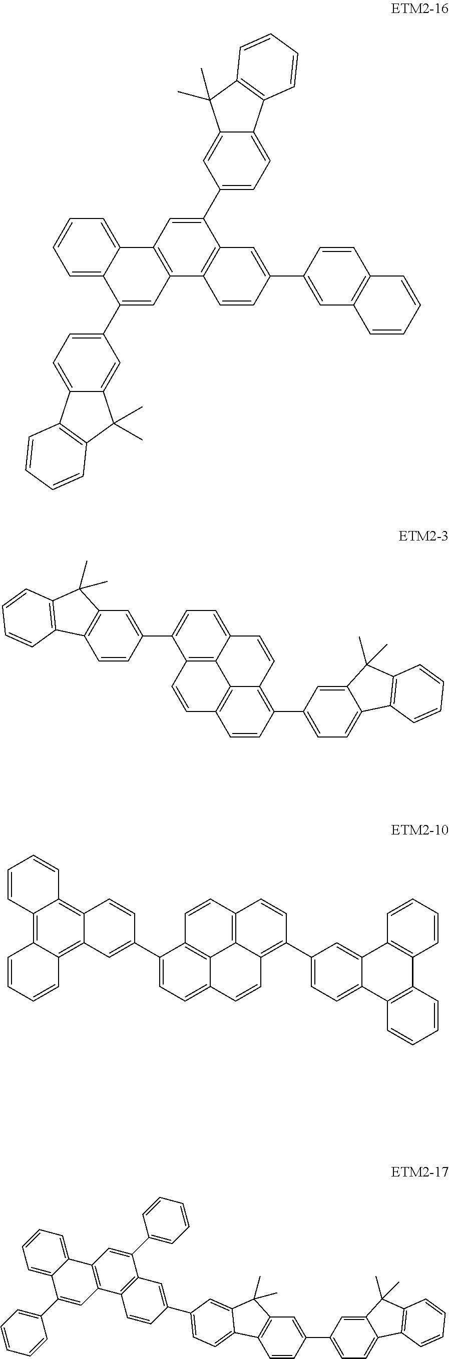

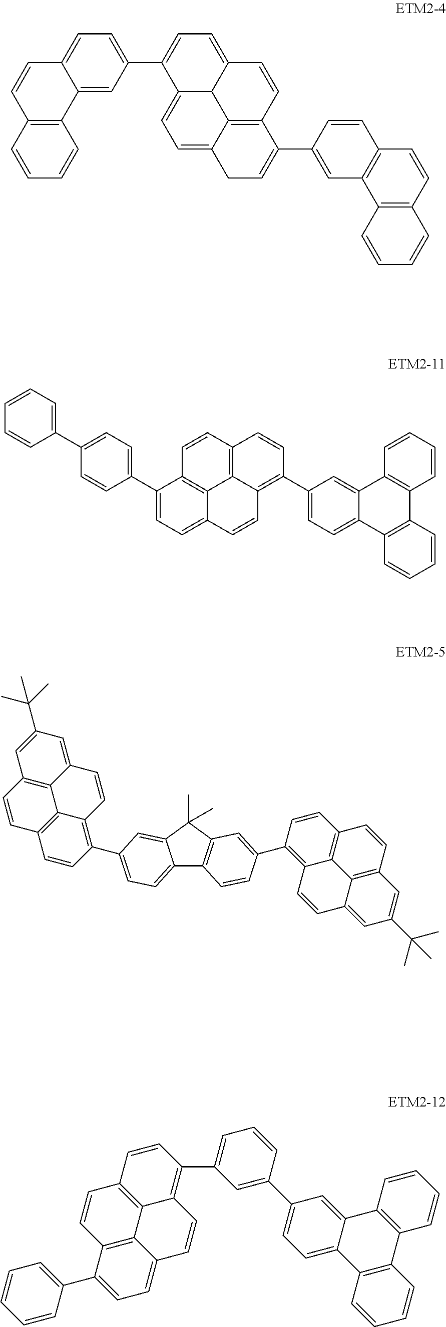

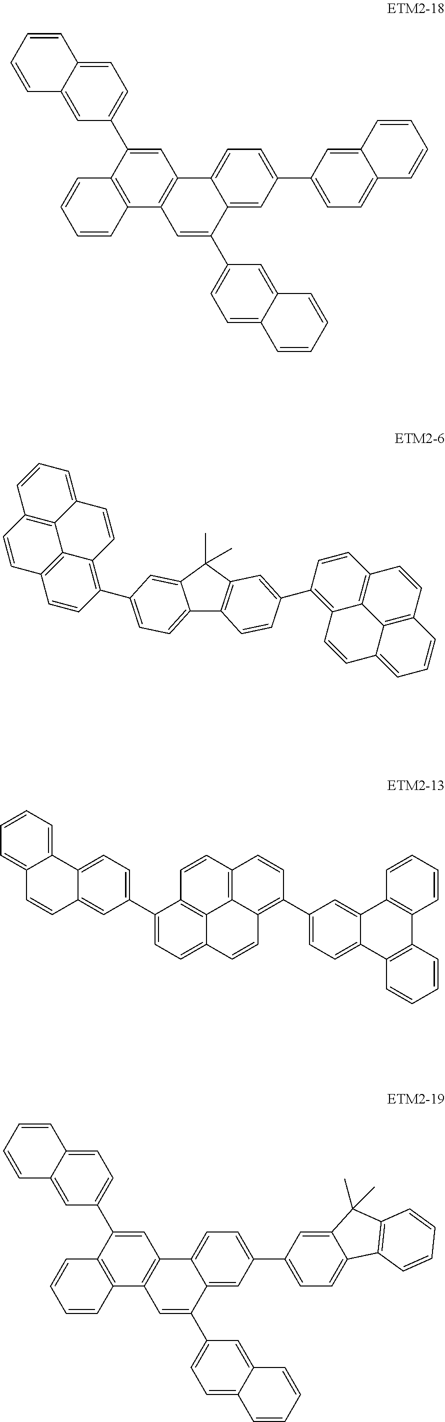

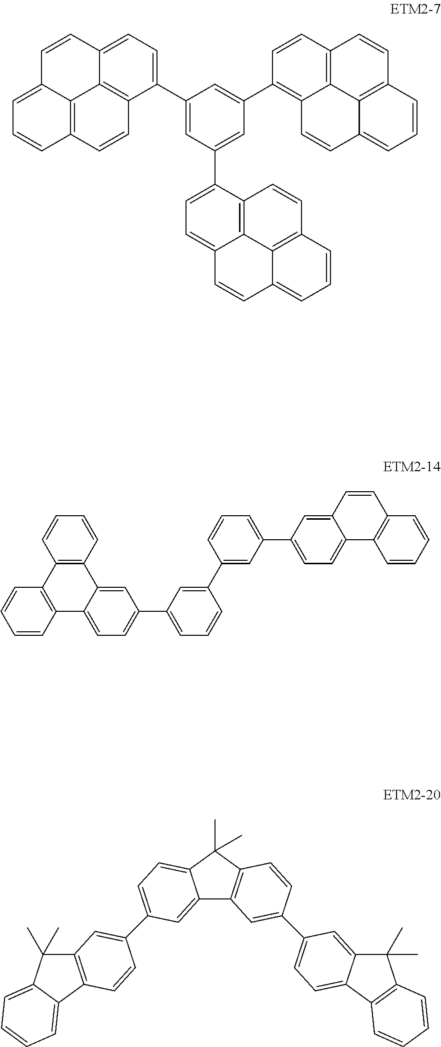

Among the above exemplified compounds, those represented by ETM2-1, 2-3, 2-5, and 2-6 have both a bulky skeleton and a highly planar skeleton, and thus exhibit superior thermal stability and can inhibit the diffusion of an n-type dopant.

(3) The charge transport layer or the charge generation layer contains a fused polycyclic hydrocarbon compound.

The charge transport layer of the organic light-emitting device according to the present embodiment preferably contains the fused polycyclic hydrocarbon compound. This is because, when a fused polycyclic hydrocarbon compound with low polarity is used in the charge transport layer, the diffusion of the n-type dopant from the charge generation region to the first light-emitting layer 303 can be inhibited. Therefore, the organic light-emitting device according to the present embodiment is an organic light-emitting device with superior durability. Similarly, the charge generation layer of the charge generation region preferably contains a fused polycyclic hydrocarbon compound. More preferably, the charge transport layer and the charge generation layer contain a fused polycyclic hydrocarbon compound.

When the charge transport layer contains a fused polycyclic hydrocarbon compound, the fused polycyclic hydrocarbon compound is preferably contained in an amount of 10 wt % or more based on the weight of the charge transport layer. More preferably, the charge transport layer is composed solely of the fused polycyclic hydrocarbon compound.

When the charge generation layer contains a fused polycyclic hydrocarbon compound, the fused polycyclic hydrocarbon compound is preferably contained in an amount of 10 wt % or more and 50 wt % or less based on the weight of the charge generation layer. This is because an increase in the concentration of the fused polycyclic hydrocarbon compound results in an increase in the driving voltage of the organic light-emitting device.

(4) The difference in LUMO energy levels between the fused polycyclic hydrocarbon compounds in the charge transport layer and the charge generation layer is small.

In the organic light-emitting device according to the present embodiment, when the charge transport layer and the charge generation layer contain the respective fused polycyclic hydrocarbon compounds, the difference in LUMO energy levels between the fused polycyclic hydrocarbon compounds contained in the layers is preferably small. When the charge transport layer functions as an electron transport layer, electrons generated in the charge generation layer are supplied to the first light-emitting layer 303 through the charge generation region 400 and the electron transport layer 304.

For this reason, when each of the charge transport layer and the charge generation layer contains a fused polycyclic hydrocarbon compound, the difference in LUMO energy levels between the fused polycyclic hydrocarbon compounds contained in the layers is preferably small. Specifically, the absolute value of the difference in LUMO energy levels is preferably 0.2 eV or less, more preferably 0.1 eV or less. As a result, the organic light-emitting device according to the present embodiment exhibits a low driving voltage and excellent durability.

Similarly, when each of the charge transport layer and the intermediate layer contains a fused polycyclic hydrocarbon compound, the difference in LUMO energy levels between the fused polycyclic hydrocarbon compounds contained in the layers is preferably small. Specifically, the absolute value of the difference in LUMO energy levels is preferably 0.2 eV or less, more preferably 0.1 eV or less.

Particularly preferably, the charge transport layer and the charge generation layer each contain the same fused polycyclic hydrocarbon compound. When the charge transport layer and the charge generation layer each contain the same fused polycyclic hydrocarbon compound, the difference in LUMO energy levels is extremely small, and therefore the organic light-emitting device according to the present embodiment exhibits a lower driving voltage and superior durability.

(5) The difference in HOMO energy levels between the fused polycyclic hydrocarbon compounds in the charge generation layer and the intermediate layer is small.

In the organic light-emitting device according to the present embodiment, when the charge generation layer and the intermediate layer contain the respective fused polycyclic hydrocarbon compounds, the difference in HOMO energy levels between the fused polycyclic hydrocarbon compounds contained in the layers is preferably small. When the charge generation layer functions as an n-type charge generation layer, holes generated in the charge generation layer are supplied to the second light-emitting layer 503 through the charge generation region 400.

For this reason, when the charge generation layer and the intermediate layer contain the respective fused polycyclic hydrocarbon compounds, the difference in HOMO energy levels between the fused polycyclic hydrocarbon compounds contained in the layers is preferably small. Specifically, the absolute value of the difference in HOMO energy levels is preferably 0.2 eV or less, more preferably 0.1 eV or less. As a result, the organic light-emitting device according to the present embodiment exhibits a low driving voltage and excellent durability.

Particularly preferably, the charge generation layer and the intermediate layer each contain the same fused polycyclic hydrocarbon compound. When the charge generation layer and the intermediate layer each contain the same fused polycyclic hydrocarbon compound, the difference in HOMO energy levels is extremely small, and therefore the organic light-emitting device according to the present embodiment exhibits a lower driving voltage and superior durability.

(6) The charge transport layer, the charge generation layer, and the intermediate layer each contain the same fused polycyclic hydrocarbon compound.

As described in (4) and (5), when the charge transport layer and the charge generation layer, and the charge generation layer and the intermediate layer are made of the same compound, an organic light-emitting device exhibiting a lower driving voltage can be provided. In other words, when the charge transport layer, the charge generation layer, and the intermediate layer contain a fused polycyclic hydrocarbon compound, these layers particularly preferably contain the same fused polycyclic hydrocarbon compound. In this case, an organic light-emitting device that exhibits a lower driving voltage and superior durability is provided.

### Other Materials

In the organic light-emitting device according to the present embodiment, conventionally known low- or high-molecular-weight hole injection or hole transport compounds, host compounds, light-emitting compounds, electron injection or electron transport compounds, and the like may also be used as needed. Examples of these compounds are described below.

A hole injection-transport material is preferably a material having a high hole mobility so as to facilitate the injection of holes from the anode and to transport the injected holes to the light-emitting layer. To reduce a deterioration in film quality, such as crystallization, in the organic light-emitting device, a material having a high glass transition temperature is preferred. Examples of low- or high-molecular-weight materials having the ability to inject and transport holes include triarylamine derivatives, aryl carbazole derivatives, phenylenediamine derivatives, stilbene derivatives, phthalocyanine derivatives, porphyrin derivatives, poly(vinyl carbazole), polythiophene, and other conductive polymers. Furthermore, the above-described hole injection-transport material is also suitable for use in an electron-blocking layer. The following are specific examples of compounds used as the hole injection-transport materials, but of course the hole injection-transport materials are not limited thereto.

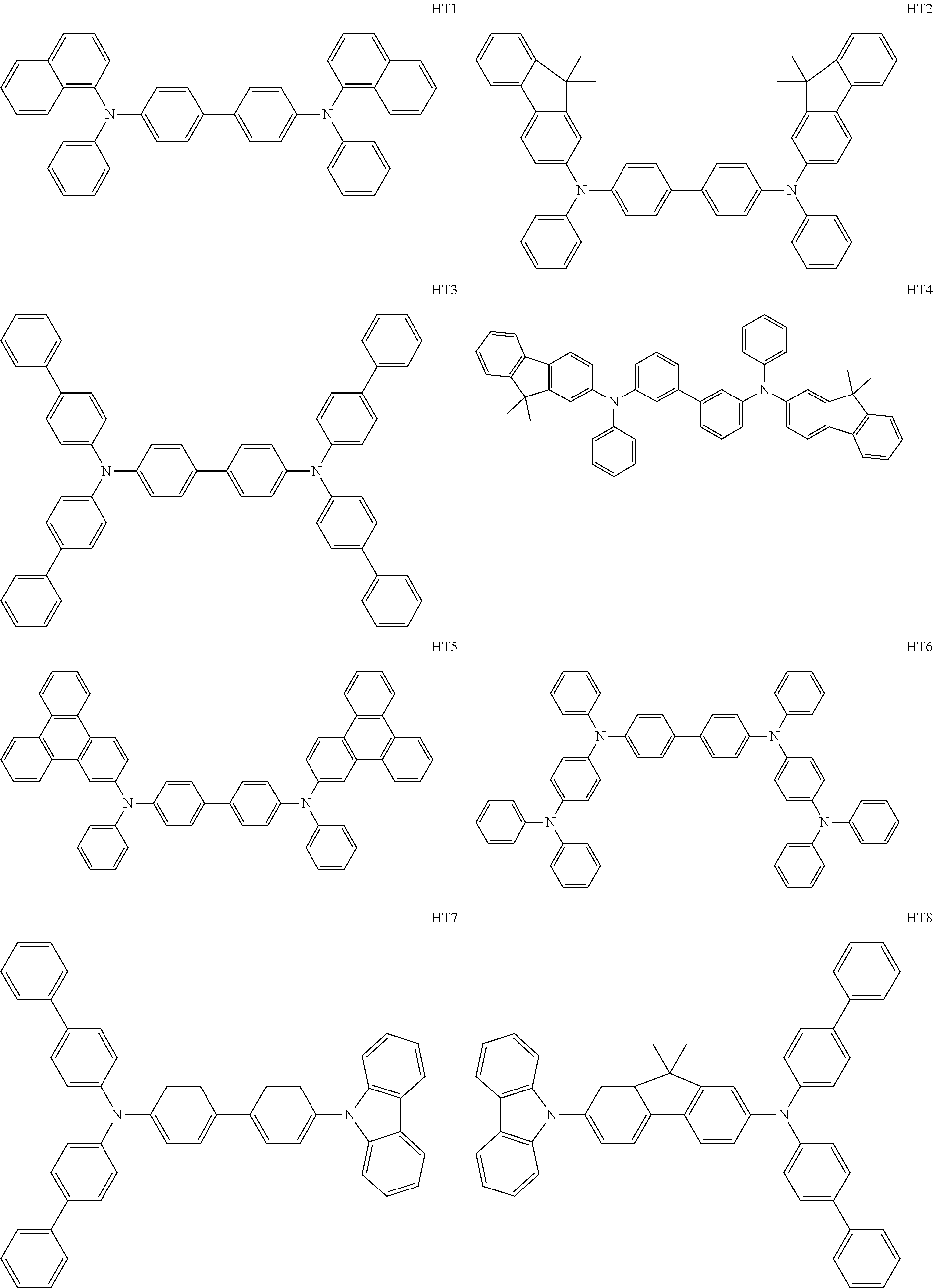

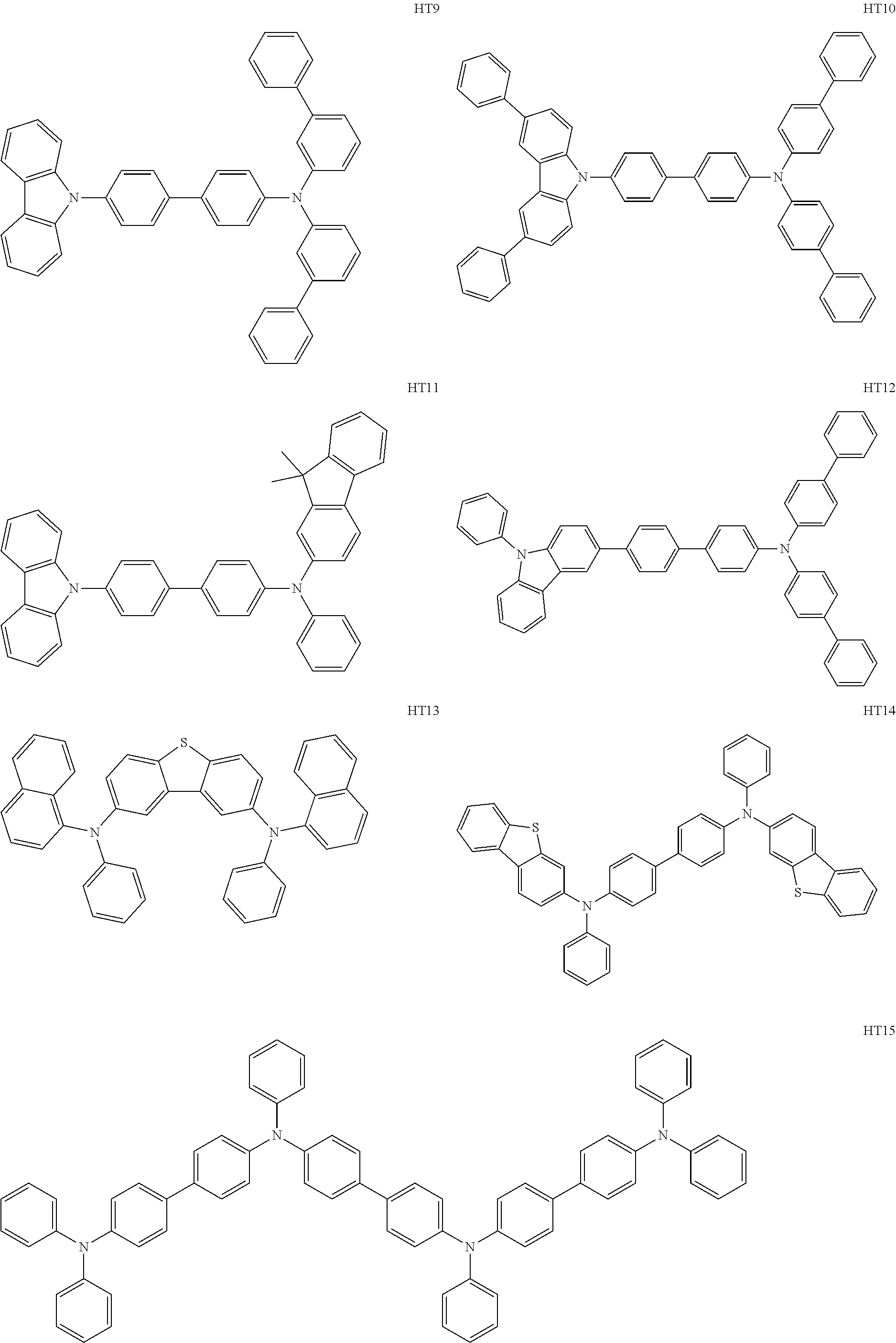

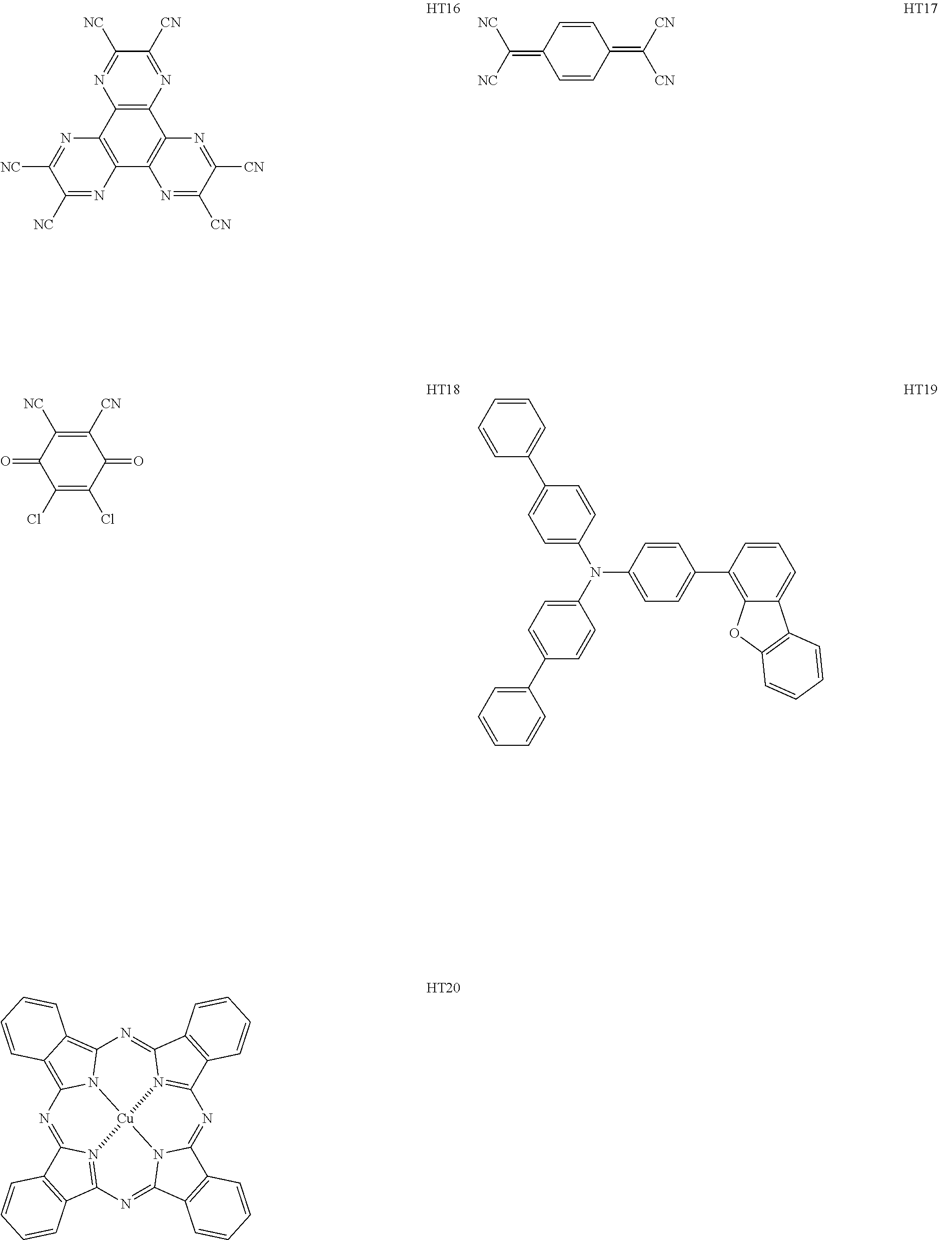

Among the hole transport materials illustrated above, HT16 to HT18 can be used in the layer in contact with the anode to reduce the driving voltage. HT16 is widely used in organic light-emitting devices. HT2, HT3, HT4, HT5, HT6, HT10, and HT12 may be used in an organic compound layer adjacent to HT16. Multiple materials may be used in a single organic compound layer.

Examples of the light-emitting material mainly related to the light-emitting function include fused-ring compounds (such as fluorene derivatives, naphthalene derivatives, pyrene derivatives, perylene derivatives, tetracene derivatives, anthracene derivatives, and rubrene), quinacridone derivatives, coumarin derivatives, stilbene derivatives, organoaluminum complexes, such as tris(8-quinolinolato)aluminum, iridium complexes, platinum complexes, rhenium complexes, copper complexes, europium complexes, ruthenium complexes, and polymer derivatives, such as poly(phenylene vinylene) derivatives, polyfluorene derivatives, and polyphenylene derivatives.

Specific examples of a compound that can be used as a light-emitting material are illustrated below, but of course the light-emitting material is not limited thereto.

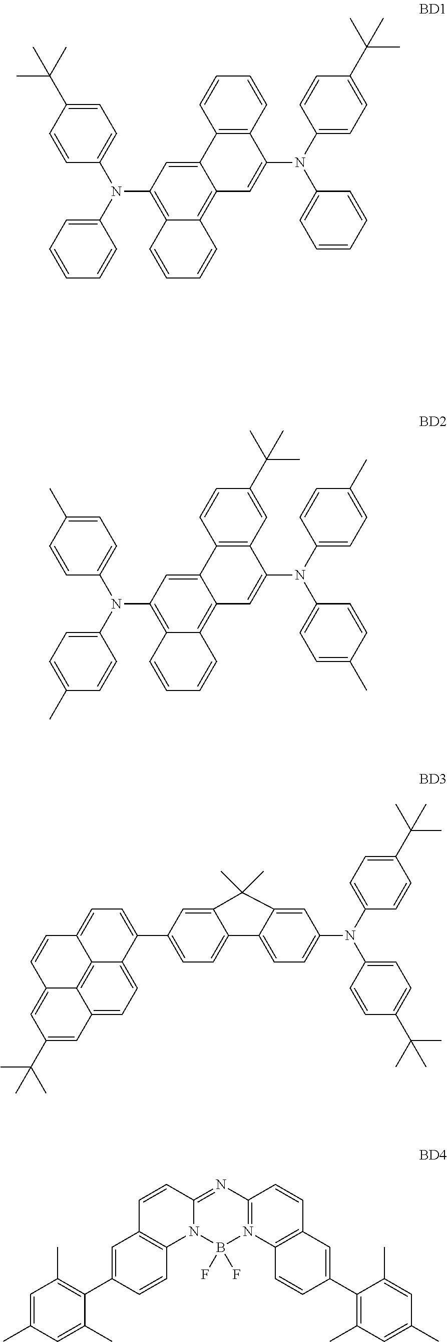

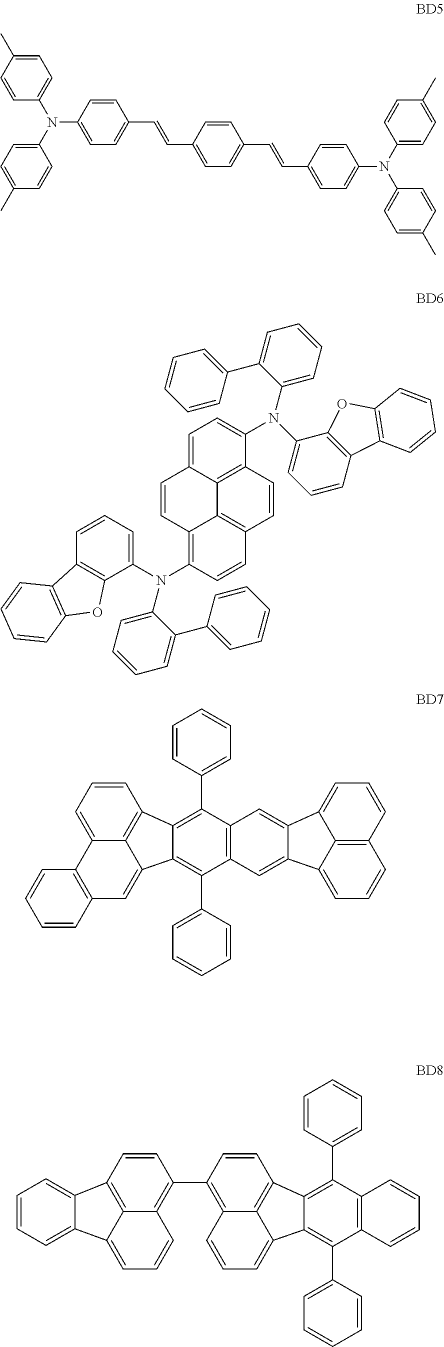

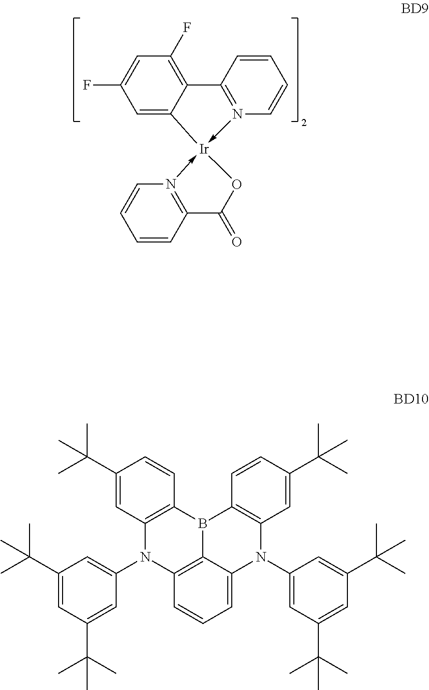

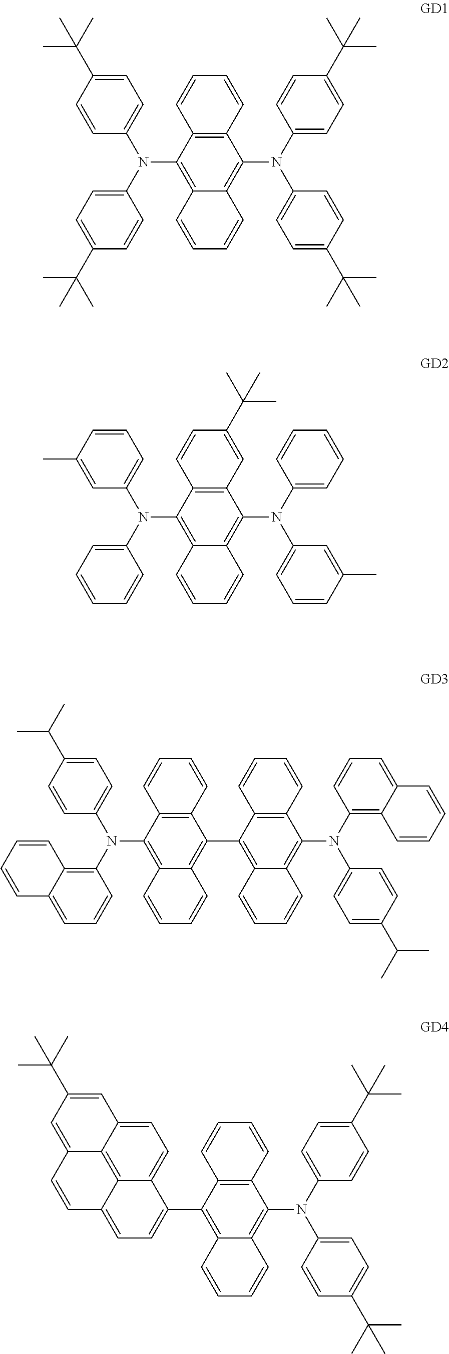

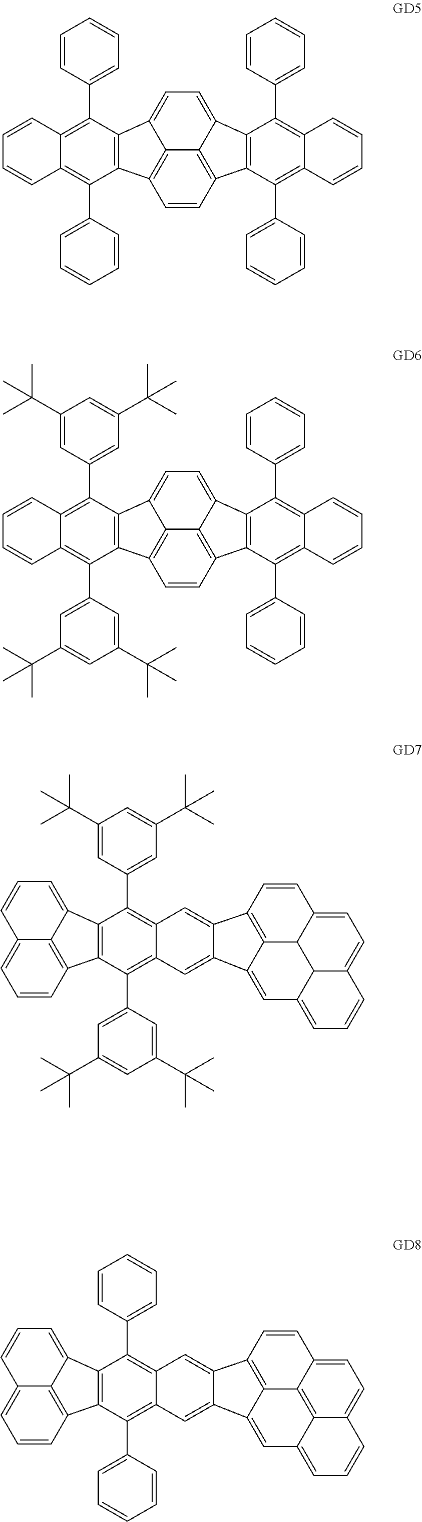

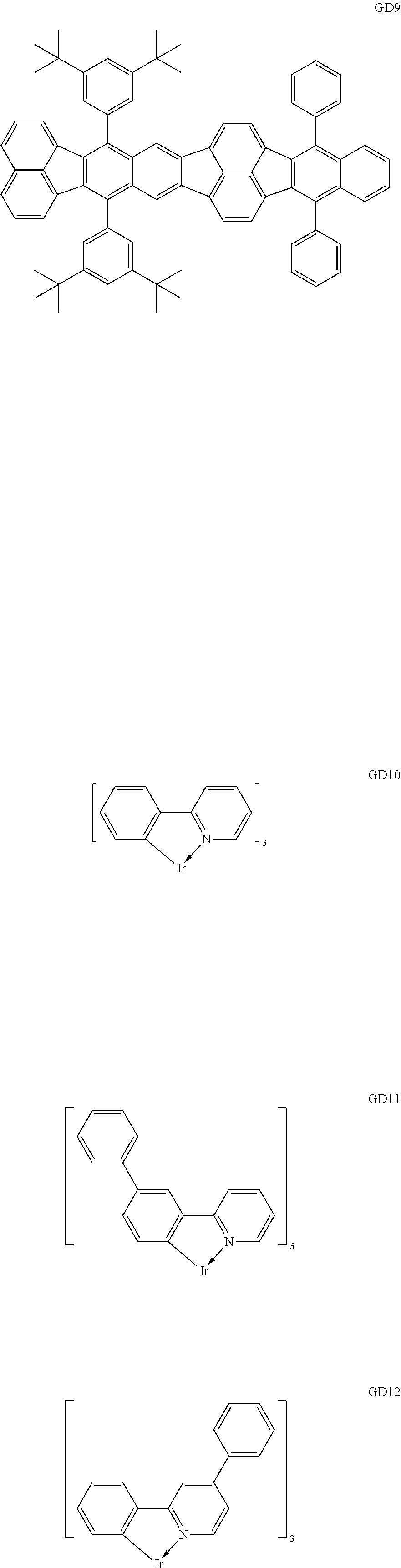

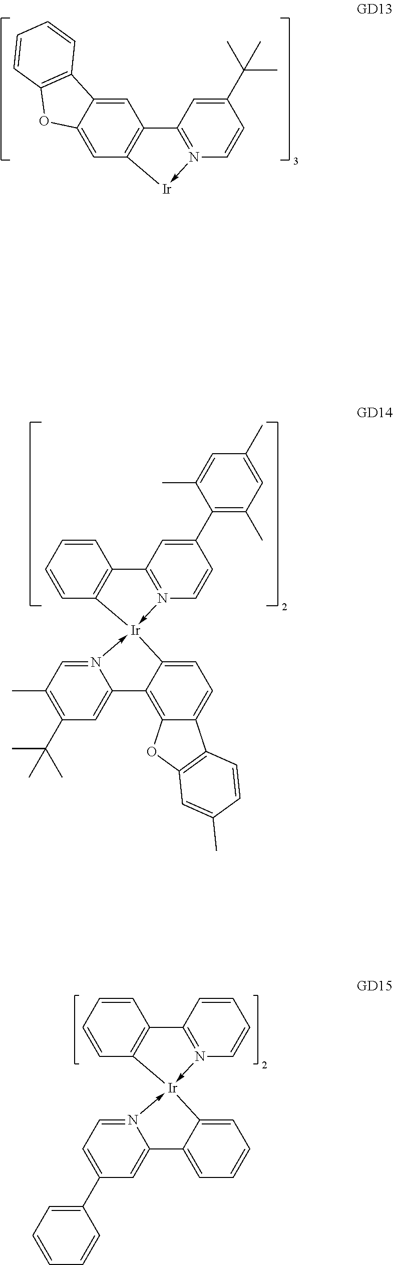

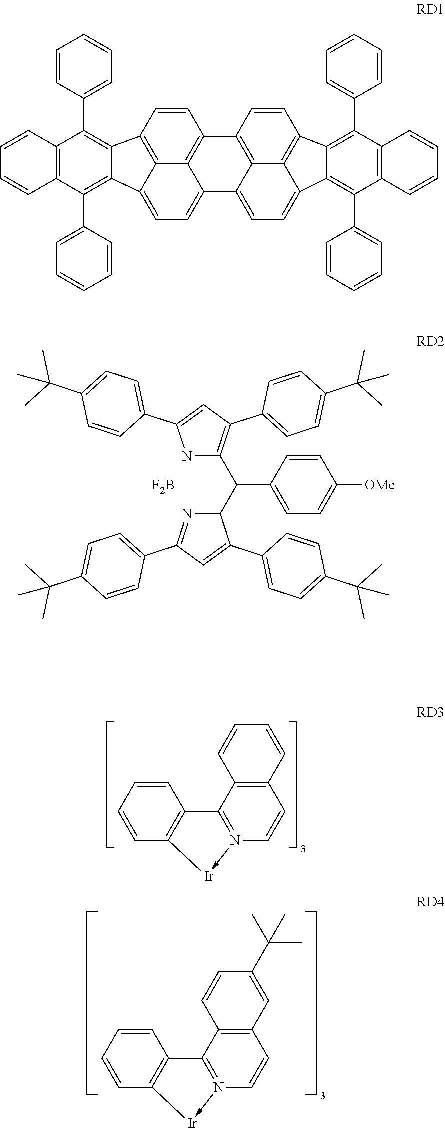

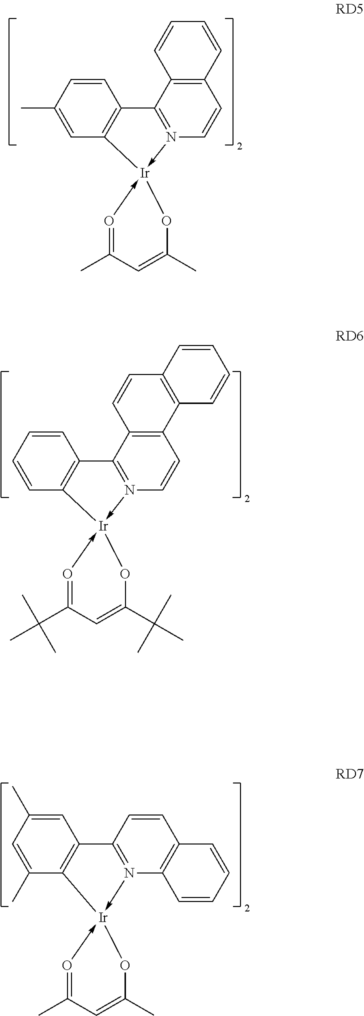

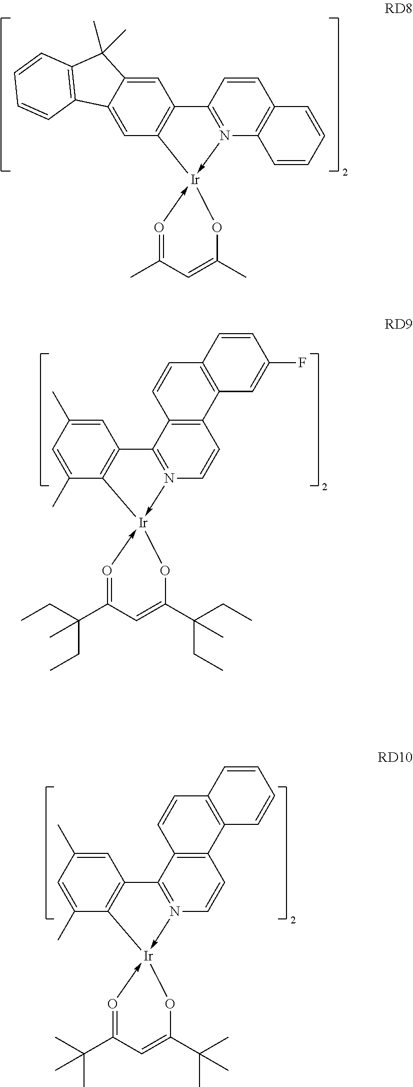

When the light-emitting material is a hydrocarbon compound, the material can reduce a decrease in luminous efficiency due to exciplex formation and a decrease in color purity due to a change in the emission spectrum of the light-emitting material caused by exciplex formation, which is preferred.

The hydrocarbon compound is a compound consisting of only carbon and hydrogen. Among the exemplified compounds illustrated above, BD7, BD8, GD5 to GD9, and RD1 are hydrocarbon compounds.

When the light-emitting material is a fused polycyclic compound containing a five-membered ring, this compound is more preferred because it has a high ionization potential and high resistance to oxidation, thus providing a highly durable device with a long lifetime. Among the exemplified compounds illustrated above, BD7, BD8, GD5 to GD9, and RD1 are categorized thereinto.

Examples of a light-emitting layer host or a light-emission assist material contained in the light-emitting layer include aromatic hydrocarbon compounds and derivatives thereof, carbazole derivatives, dibenzofuran derivatives, dibenzothiophene derivatives, organoaluminum complexes, such as tris(8-quinolinolato)aluminum, and organoberyllium complexes.

Specific examples of the compound for the light-emitting layer host or light-emission assist material contained in the light-emitting layer are illustrated below, but of course the compound is not limited thereto.

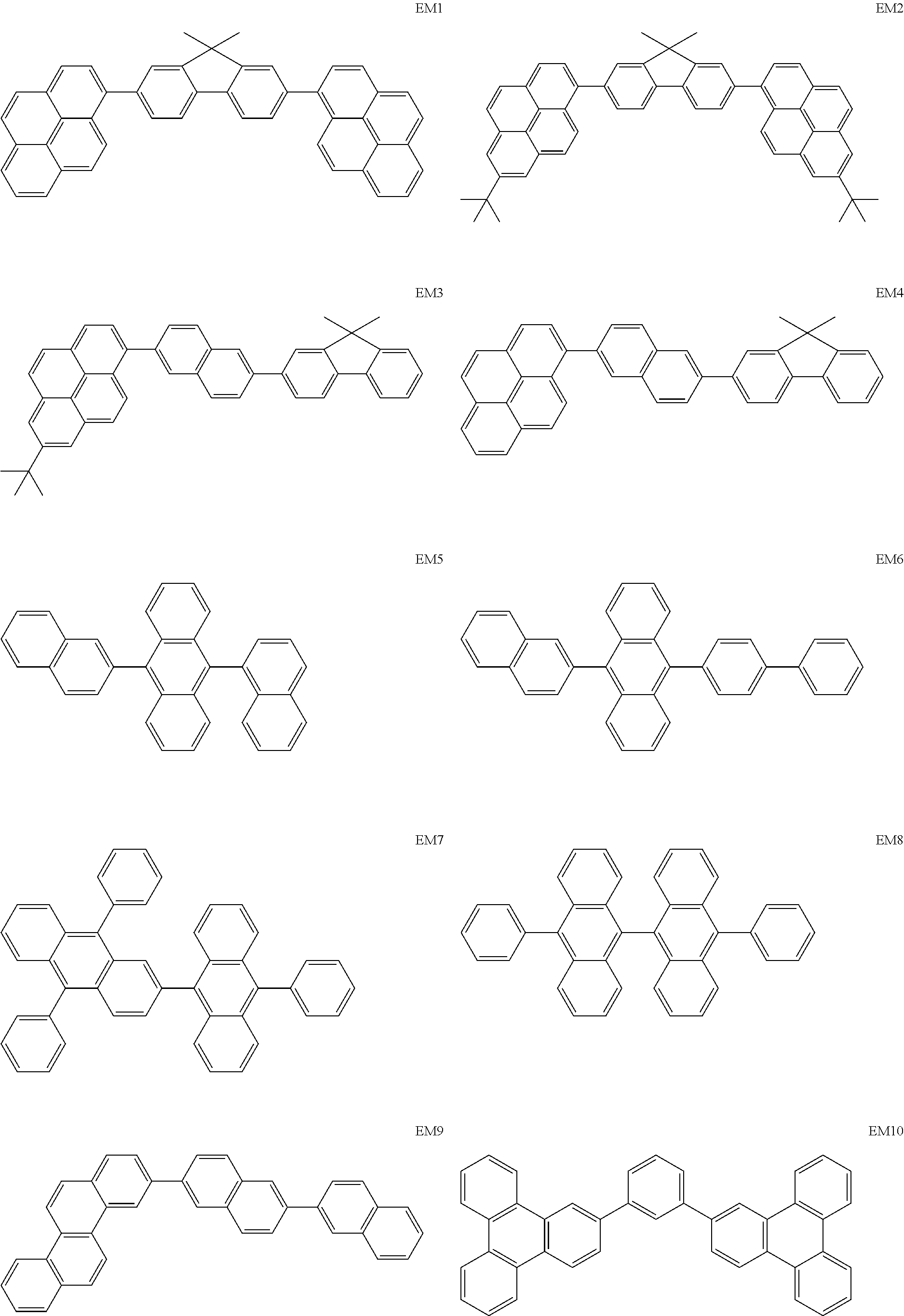

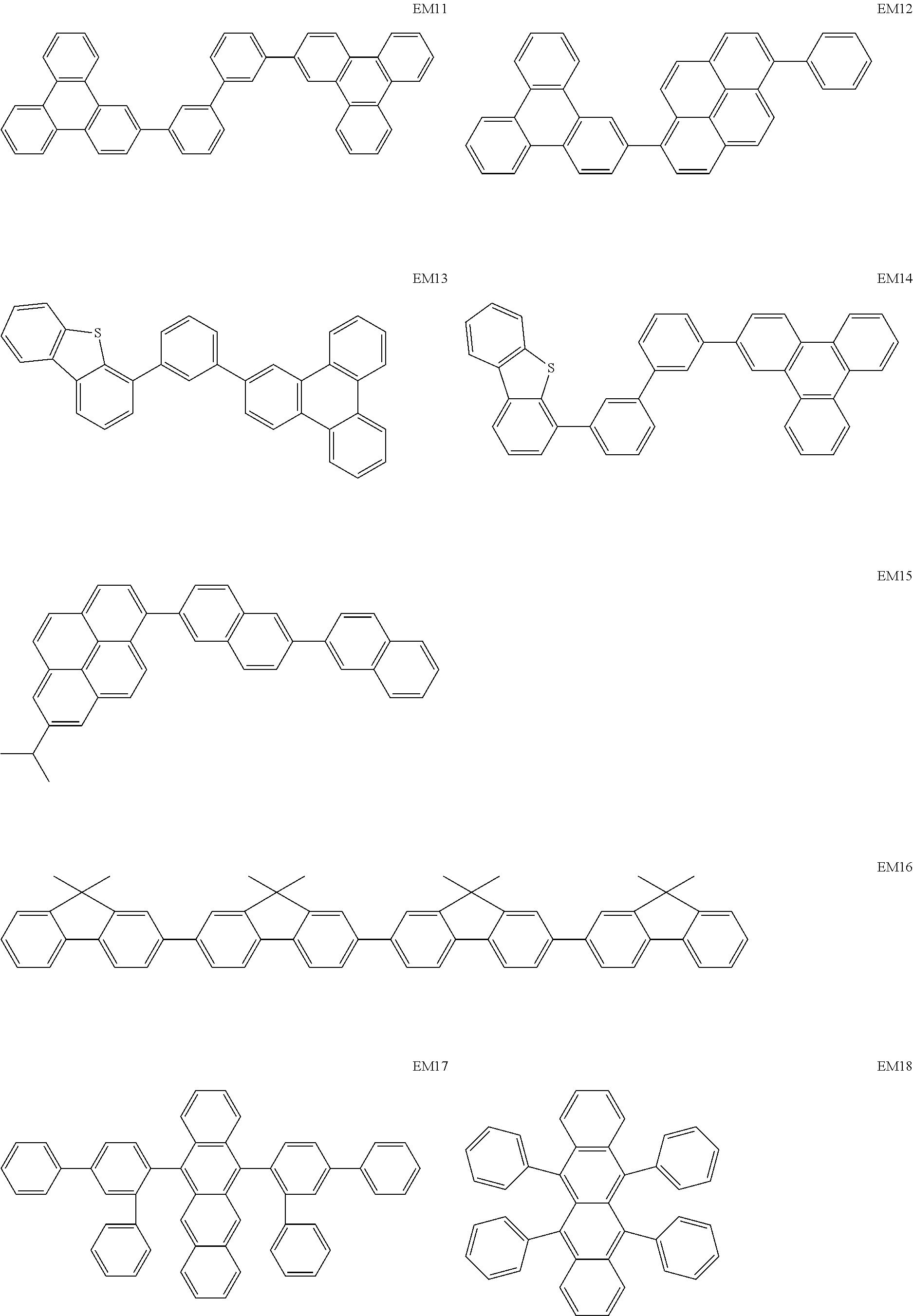

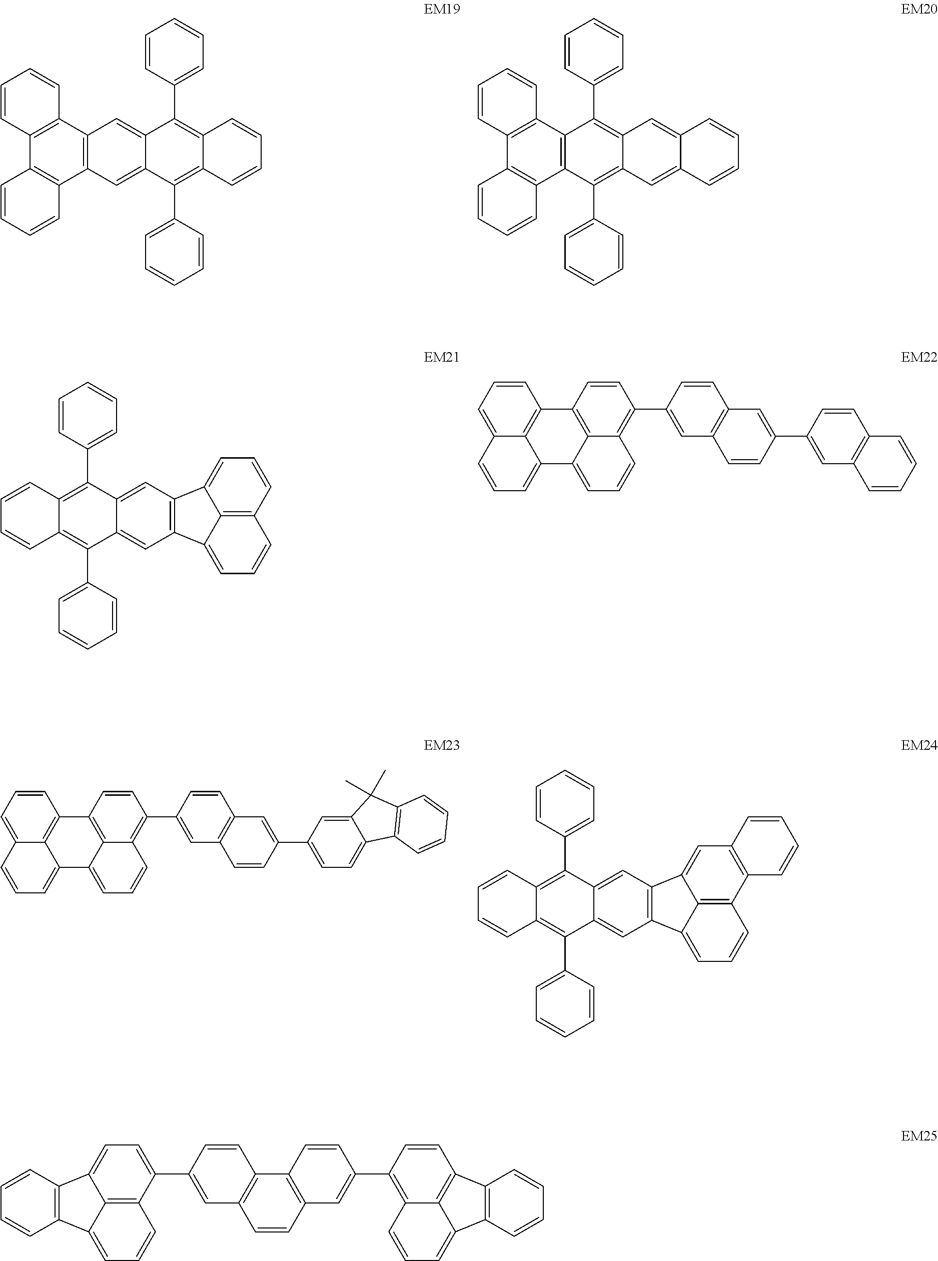

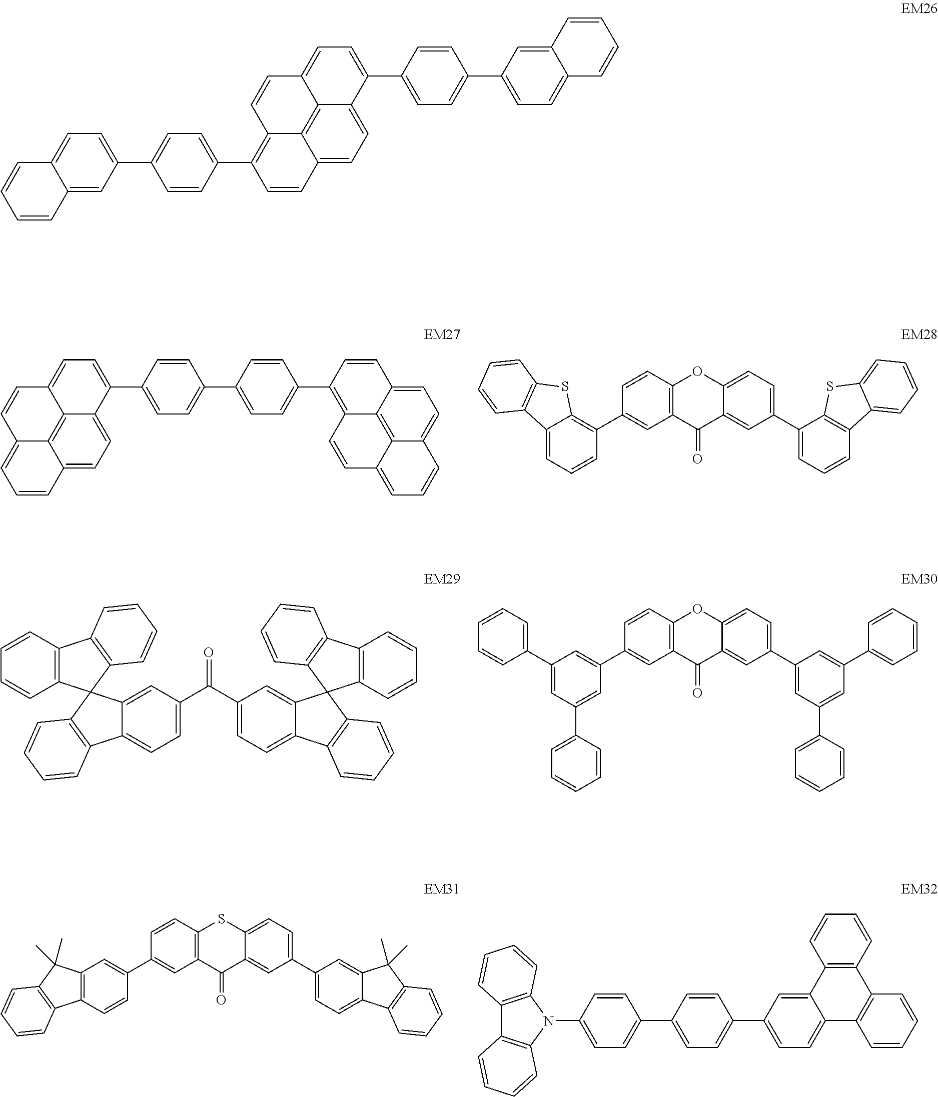

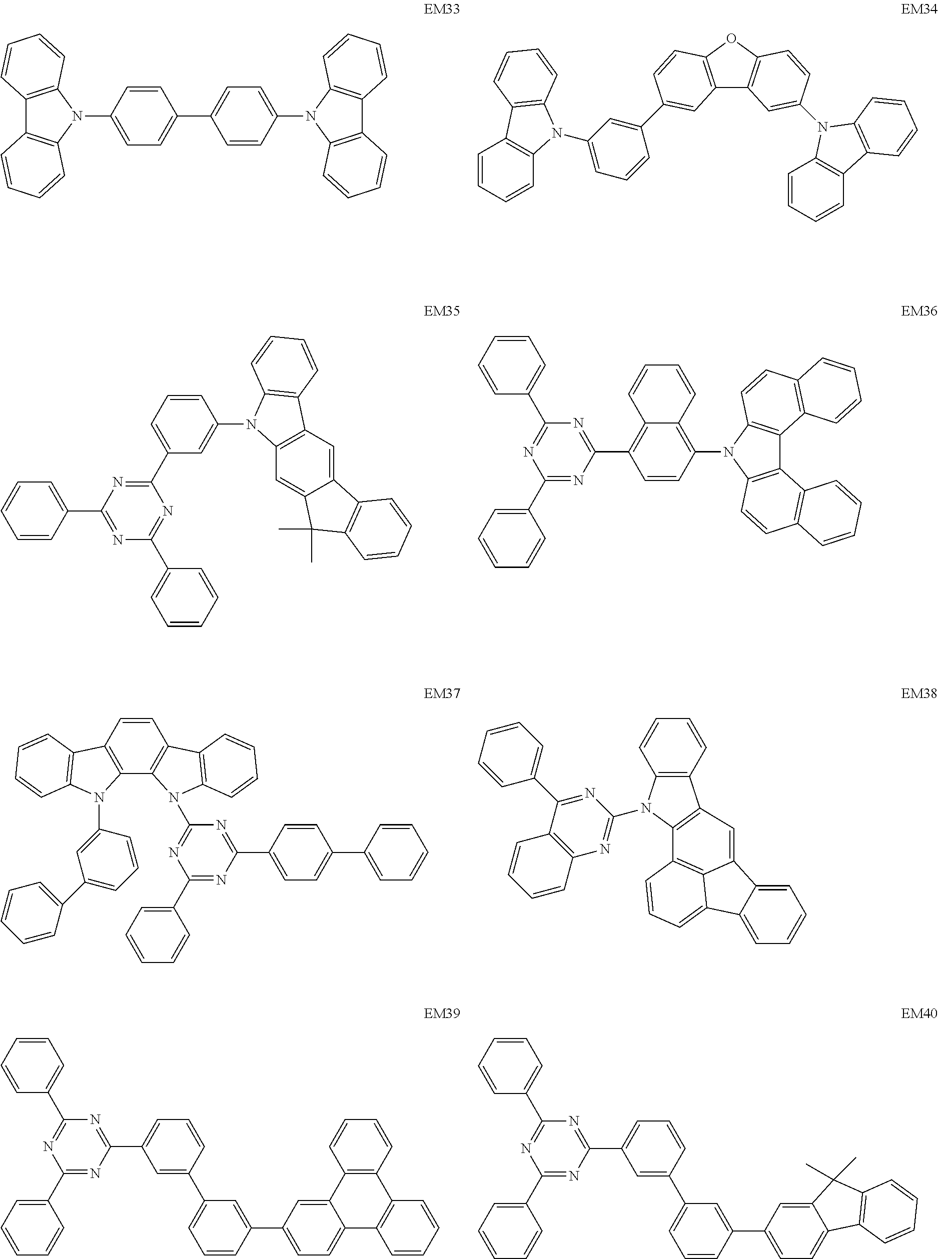

The host material is preferably a hydrocarbon compound. The hydrocarbon compound is a compound consisting of only carbon and hydrogen. Among the exemplified compounds illustrated above, EM1 to EM12 and EM16 to EM27 are hydrocarbon compounds. As the host material, those that do not have carbon-heteroatom bonds in the single bonds connecting aryl group units within their structure are preferred from the viewpoint of stability.

The electron transport material can be freely-selected from materials that can transport electrons injected from the cathode to the light-emitting layer and is selected in consideration of, for example, the balance with the hole mobility of the hole transport material. Examples of a material having the ability to transport electrons include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused-ring compounds, such as fluorene derivatives, naphthalene derivatives, chrysene derivatives, and anthracene derivatives. The above-described electron transport materials are also suitably used for the hole-blocking layer.

Specific examples of a compound used as the electron transport material are illustrated below, but of course the compound is not limited thereto.

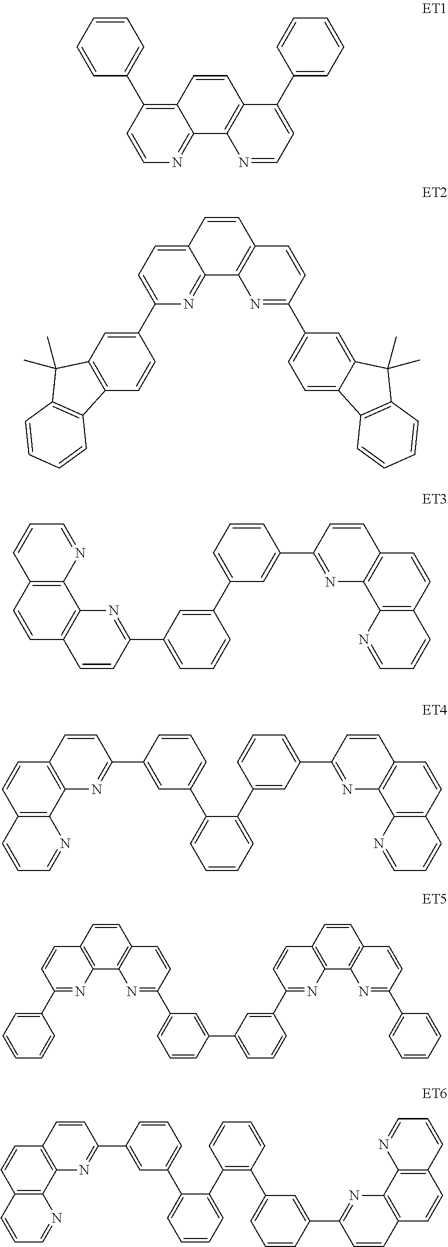

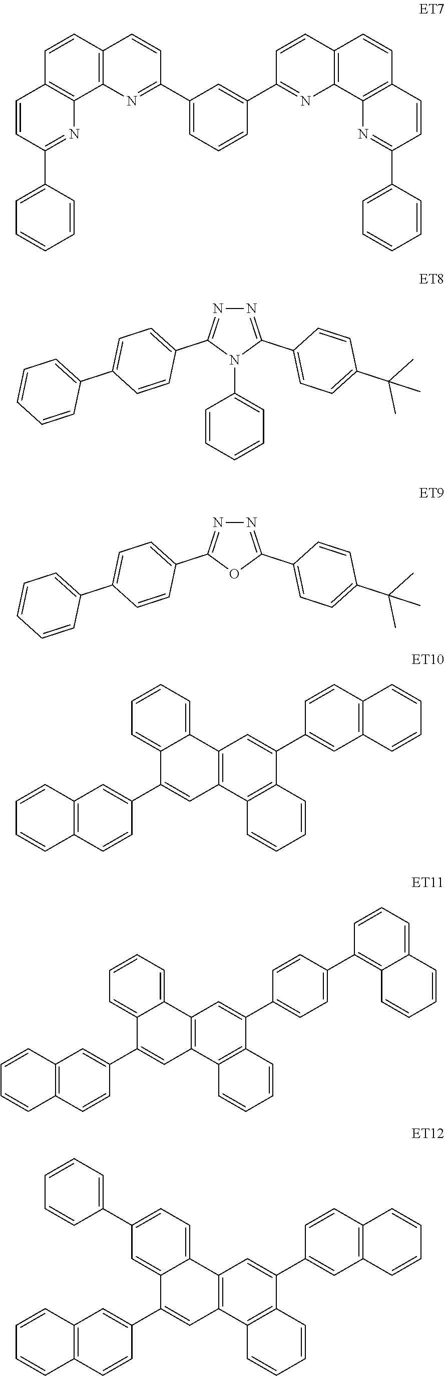

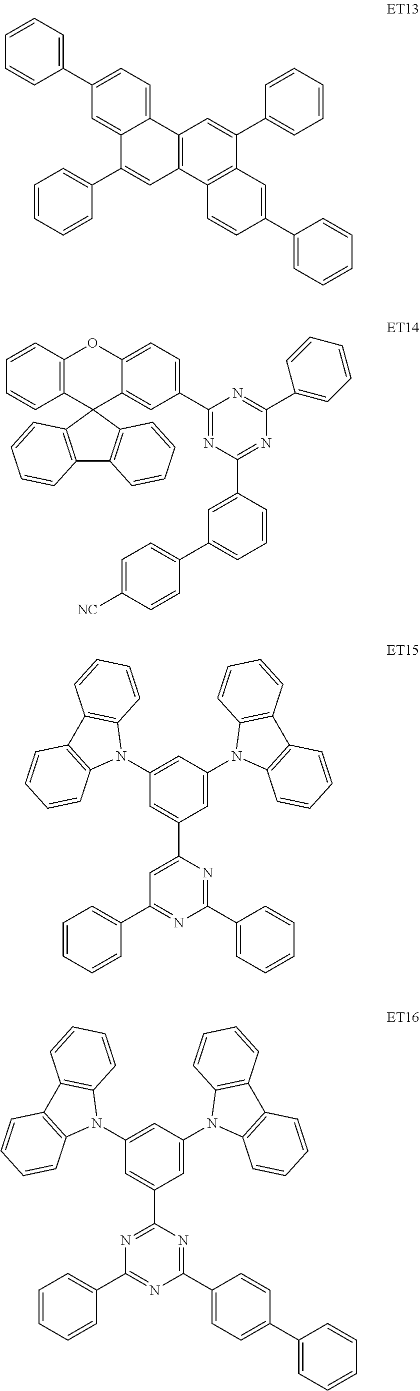

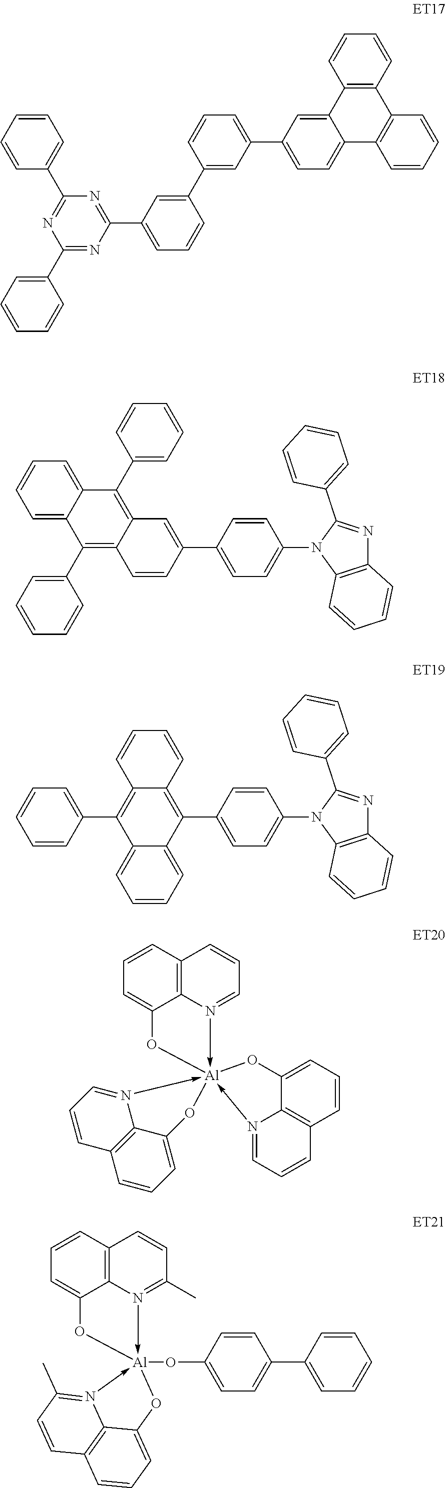

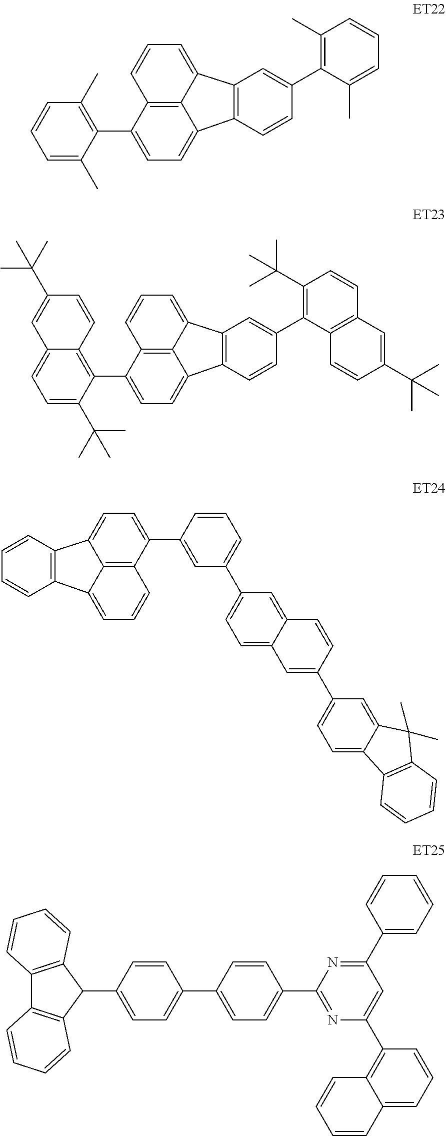

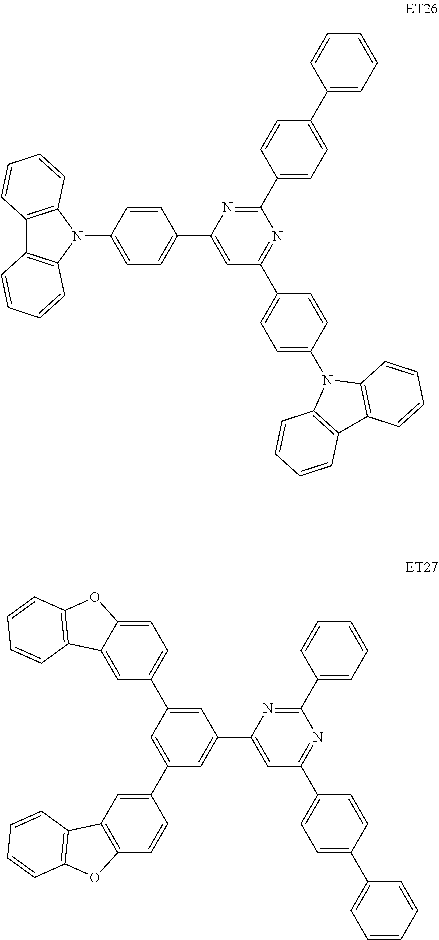 [SMILES: c1ccc(-c2ccc(-c3nc(-c4ccc(-n5c6ccccc6c6ccccc65)cc4)cc(-c4ccc(-n5c6ccccc6c6ccccc65)cc4)n3)cc2)cc1 ; c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

An electron injection material can be freely-selected from materials into which electrons can be easily injected from the cathode and is selected in consideration of, for example, the balance with the hole injection properties. As the organic compound, n-type dopants and reducing dopants are also included. Examples thereof include alkali metal-containing compounds, such as lithium fluoride, lithium complexes, such as lithium quinolinolate, benzimidazolidene derivatives, imidazolidene derivatives, fulvalene derivatives, and acridine derivatives.

### Configuration of Organic Light-Emitting Device

Constituent members included in the organic light-emitting device of the present embodiment will be described below.

The organic light-emitting device includes, over the substrate, an insulating layer, the first electrode, the organic compound layers, and the second electrode. A protective layer, a color filter, a microlens, and so forth may be disposed over the second electrode. In the case of disposing the color filter, a planarization layer may be disposed between the protective layer and the color filter. The planarization layer can be composed of, for example, an acrylic resin. The same applies when a planarization layer is provided between the color filter and the microlens.

### Substrate

Examples of the substrate include quartz, glass, silicon wafers, resins, and metals. The substrate may include a switching element, such as a transistor, a line, and an insulating layer thereon. Any material can be used for the insulating layer as long as a contact hole can be formed in such a manner that a line can be coupled to the first electrode and as long as insulation with a non-connected line can be ensured. For example, a resin, such as polyimide, silicon oxide, or silicon nitride, can be used.

### Electrode

As electrodes, the first electrode and the second electrode can be used. The first electrode and the second electrode may be an anode and a cathode. When an electric field is applied in the direction in which the organic light-emitting device emits light, an electrode having a higher potential is the anode, and the other is the cathode. It can also be said that the electrode that supplies holes to the light-emitting layer is the anode and that the electrode that supplies electrons is the cathode.

As a constituent material of the anode, a material having a work function as large as possible is preferred. Examples of the material that can be used include elemental metals, such as gold, platinum, silver, copper, nickel, palladium, cobalt, selenium, vanadium, and tungsten, mixtures thereof, alloys of combinations thereof, and metal oxides, such as tin oxide, zinc oxide, indium oxide, indium-tin oxide (ITO), and indium-zinc oxide. Additionally, conductive polymers, such as polyaniline, polypyrrole, and polythiophene, can also be used.

These electrode materials may be used alone or in combination of two or more. The anode may be formed of a single layer or multiple layers.

When the electrode is used as a reflective electrode, for example, chromium, aluminum, silver, titanium, tungsten, molybdenum, an alloy thereof, or a stack thereof can be used. These materials can also be used to act as a reflective film that does not have the role of an electrode. When the electrode is used as a transparent electrode, a transparent conductive oxide layer composed of, for example, indium-tin oxide (ITO) or indium-zinc oxide can be used; however, the electrode is not limited thereto. The electrode can be formed by photolithography.

As a constituent material of the cathode, a material having a small work function is preferred. Examples thereof include elemental metals, such as alkali metals, e.g., lithium, alkaline-earth metals, e.g., calcium, aluminum, titanium, manganese, silver, lead, and chromium, and mixtures containing them. Alternatively, an alloy made by combining these metal elements can also be used. For example, magnesium-silver, aluminum-lithium, aluminum-magnesium, silver-copper, zinc-silver, and so forth can be used. Metal oxides, such as indium-tin oxide (ITO), can also be used. These electrode materials may be used alone or in combination of two or more. The cathode may have a single-layer structure or a multilayer structure. In particular, silver is preferably used. To reduce the aggregation of silver, a silver alloy is more preferred. Any alloy ratio may be used as long as the aggregation of silver can be reduced. The ratio of silver to another metal may be, for example, 1:1 or 3:1.

A top emission device may be provided using the cathode formed of a conductive oxide layer composed of, for example, ITO. A bottom emission device may be provided using the cathode formed of a reflective electrode composed of, for example, aluminum (Al). The cathode is not particularly limited. A method for forming the cathode is not particularly limited, but a direct-current sputtering method, an alternating-current sputtering method, or the like is more preferably used because good film coverage is obtained and thus the resistance is easily reduced.

### Organic Compound Layer

The organic compound layer may be formed of a single layer or multiple layers. When multiple layers are provided, they may be called a hole injection layer, a hole transport layer, an electron-blocking layer, a light-emitting layer, a hole-blocking layer, an electron transport layer, or an electron injection layer in accordance with their functions. The organic compound layer is mainly composed of an organic compound, and may contain inorganic atoms and an inorganic compound. For example, each organic compound layer may contain, for example, copper, lithium, magnesium, aluminum, iridium, platinum, molybdenum, or zinc. The organic compound layer may be disposed between the first electrode and the second electrode, and may be disposed in contact with the first electrode and the second electrode.

When multiple light-emitting layers are provided, a charge generation region may be provided between a first light-emitting layer and a second light-emitting layer. The charge generation region is formed by forming an n/p junction with a p-type organic semiconductor layer and an n-type organic semiconductor layer, or by using a p-type doped layer and an n-type doped layer. For example, when the charge generation region is formed only by a p/n junction, it is preferable to provide an electron injection layer for injecting generated electrons into the electron transport layer. An n-type doped layer/p-type doped layer may be used. The configuration of the charge generation layer of the present disclosure is not limited to the above.

For the p-type doped layer, for example, a mixture of a Lewis acid, such as HAT-CN or molybdenum oxide, which has high electron-withdrawing ability, and an aromatic amine compound may be used. HAT-CN, molybdenum oxide, and so forth are n-type materials. These n-type materials may be used to form a stacked structure in which electrons are extracted from an adjacent layer to generate charges. A p-type doped layer or an np junction composed of a stack of an n-type material and a p-type material is referred to as a p-type charge generation layer.

For the n-type doped layer, for example, a material having a low work function which is easily doped with electrons, such as an alkali metal atom or alkaline-earth metal atom, is used. The n-type doped layer is referred to as an n-charge generation layer. Alternatively, LiF or the like may be combined with a thin film of a reducing metal to form an electron injection layer, and an n-type layer/p-type layer structure may be formed to generate charges.

Examples of an n-type dopant that can be used include alkali metal atoms, alkaline-earth metal atoms, rare-earth metal atoms, and compounds thereof, such as alkali metal compounds including oxides, such as lithium oxide, halides, and carbonates, such as lithium carbonate and cesium carbonate, alkaline-earth metal compounds including oxides, halides, and carbonates thereof, and rare-earth metal compounds including oxides, halides, and carbonates thereof. Organic compounds, such as tetrathianaphthacene (abbreviated name: TTN), nickelocene, and decamethylnickelocene, can also be used.

The concentration of the n-type dopant is not particularly limited. A higher concentration is generally preferred; however, this leads to a highly conductive layer, facilitating leakage between adjacent pixels. In contrast, when the concentration is low, the ability to inject the generated charges into the first light-emitting layer decreases. Therefore, the concentration is preferably 0.1 to 5 wt %, more preferably 0.5 to 2 wt %.

For the organic compound layer included in the organic light-emitting device according to the present embodiment, a dry process, such as a vacuum evaporation method, an ionized evaporation method, sputtering, or plasma, can be employed. Alternatively, instead of the dry process, it is also possible to employ a wet process in which a material is dissolved in an appropriate solvent and then a film is formed by a known coating method (for example, spin coating, dipping, a casting method, an LB technique, or an ink jet method).

When the layer is formed by, for example, the vacuum evaporation method or the solution coating method, crystallization and so forth are less likely to occur, and good stability with time is obtained. In the case of forming a film by the coating method, the film can be formed in combination with an appropriate binder resin.

Examples of the binder resin include, but are not limited to, polyvinyl carbazole resins, polycarbonate resins, polyester resins, ABS resins, acrylic resins, polyimide resins, phenolic resins, epoxy resins, silicon resins, and urea resins.

These binder resins may be used alone as a homopolymer or copolymer or in combination as a mixture of two or more. Furthermore, additives, such as a known plasticizer, antioxidant, and ultraviolet absorber, may be used, as needed.

### Protective Layer

A protective layer may be disposed on the second electrode. For example, a glass member provided with a moisture absorbent can be bonded to the second electrode to reduce the entry of, for example, water into the organic compound layer, thereby reducing the occurrence of display defects. In another embodiment, a passivation film composed of, for example, silicon nitride may be disposed on the second electrode to reduce the entry of, for example, water into the organic compound layer. For example, after the formation of the second electrode, the substrate may be transported to another chamber without breaking the vacuum, and a silicon nitride film having a thickness of 2 μm may be formed by a CVD method to provide a protective layer. After the film deposition by the CVD method, a protective layer may be formed by an atomic layer deposition (ALD) method. Examples of the material of the layer formed by the ALD method may include, but are not limited to, silicon nitride, silicon oxide, and aluminum oxide. Silicon nitride may be deposited by the CVD method on the layer formed by the ALD method. The film formed by the ALD method may have a smaller thickness than the film formed by the CVD method. Specifically, it may be 50% or less, or even 10% or less.

### Color Filter

A color filter may be disposed on the protective layer. For example, a color filter may be disposed on another substrate in consideration of the size of the organic light-emitting device and bonded to the substrate provided with the organic light-emitting device. A color filter may be formed by patterning on the protective layer using photolithography. The color filter may be composed of a polymer.

### Planarization Layer

A planarization layer may be disposed between the color filter and the protective layer. The planarization layer is provided for the purpose of reducing the unevenness of the layer underneath. The planarization layer may be referred to as a material resin layer without limiting its purpose. The planarization layer may be composed of an organic compound, may have a low- or high-molecular-weight compound, and is preferably a high-molecular-weight compound.

The planarization layers may be disposed above and below the color filter and may be composed of the same or different constituent materials. Specific examples thereof include poly(vinyl carbazole) resins, polycarbonate resins, polyester resins, ABS resins, acrylic resins, polyimide resins, phenolic resins, epoxy resins, silicone resins, and urea resins.

### Microlens

The organic light-emitting device according to the present embodiment may include an optical member, such as a microlens, on the light-emitting side. The microlens can be composed of, for example, an acrylic resin or an epoxy resin. The microlens may be used to increase the amount of light emitted from the organic light-emitting device and to control the direction of the light emitted. The microlens may have a hemispherical shape. In the case of a hemispherical shape, among tangents to the hemisphere, there is a tangent parallel to the insulating layer. The point of contact of the tangent with the hemisphere is the vertex of the microlens. The vertex of the microlens can be determined in the same way for any cross-sectional view. That is, among the tangents to the semicircle of the microlens in the cross-sectional view, there is a tangent parallel to the insulating layer, and the point of contact of the tangent with the semicircle is the vertex of the microlens.

The midpoint of the microlens can be defined. In the cross section of the microlens, when a segment is hypothetically drawn from the point where an arc shape ends to the point where another arc shape ends, the midpoint of the segment can be referred to as the midpoint of the microlens. The cross section to determine the vertex and midpoint may be a cross section perpendicular to the insulating layer.

### Opposite Substrate

An opposite substrate may be disposed on the planarization layer. The opposite substrate is disposed at a position corresponding to the substrate described above and thus is called an opposite substrate. The opposite substrate may be composed of the same constituent material as that of the substrate described above. When the above-described substrate is referred to as a first substrate, the opposite substrate may be referred to as a second substrate.

### Pixel Circuit

A light-emitting apparatus may include a pixel circuit connected to the organic light-emitting device according to the present embodiment. Each of the pixel circuits may be of an active matrix type, which independently controls the emission of multiple organic light-emitting devices. The active matrix-type circuit may be voltage-programmed or current-programmed. A driving circuit includes the pixel circuit for each pixel. The pixel circuit may include the organic light-emitting device, a transistor to control the luminance of the organic light-emitting device, a transistor to control the timing of the light emission, a capacitor to retain the gate voltage of the transistor to control the luminance, and a transistor to connect to GND without using the light-emitting device.

The light-emitting apparatus includes a display area and a peripheral area disposed around the display area. The display area includes a pixel circuit, and the peripheral area includes a display control circuit. The mobility of a transistor contained in the pixel circuit may be lower than the mobility of a transistor contained in the display control circuit. The slope of the current-voltage characteristics of the transistor contained in the pixel circuit may be smaller than the slope of the current-voltage characteristic of the transistor contained in the display control circuit. The slope of the current-voltage characteristics can be measured by what is called Vg-Ig characteristics. The transistor contained in the pixel circuit is a transistor coupled to an organic light-emitting device.

### Pixel

A light-emitting apparatus including an organic light-emitting device according to the present embodiment may include multiple pixels. Each pixel includes subpixels configured to emit colors different from each other. The subpixels may have respective RGB emission colors.

Light emerges from a region of the pixel, also called a pixel aperture. The pixel aperture may be 15 μm or less, and may be 5 μm or more. More specifically, the pixel aperture may be, for example, 11 μm, 9.5 μm, 7.4 μm, or 6.4 μm. The distance between subpixels may be 10 μm or less. Specifically, the distance may be 8 μm, 7.4 μm, or 6.4 μm.

The pixels may be arranged in a known configuration in plan view. For example, a stripe pattern, a delta pattern, a PenTile matrix pattern, or the Bayer pattern may be used. The shape of each subpixel in plan view may be any known shape. Examples thereof include quadrilaterals, such as rectangles and rhombi, and hexagons. Of course, if the shape is close to a rectangle, rather than an exact shape, it is included in the rectangle. The shape of the subpixel and the pixel arrangement can be used in combination.

### Application of Organic Light-Emitting Device

The organic light-emitting device according to the present embodiment can be used as a component member of a display apparatus or lighting apparatus. Other applications include exposure light sources for electrophotographic image-forming apparatuses, backlights for liquid crystal display apparatuses, and light-emitting apparatuses including white light sources provided with color filters.

The display apparatus may be an image information-processing apparatus including an image input unit that receives image information from an area CCD, a linear CCD, a memory card, or the like, an information-processing unit that processes the input information, and a display unit that displays the input image. The display apparatus includes multiple pixels, and at least one of the multiple pixels may include the organic light-emitting device of the present embodiment and a transistor coupled to the organic light-emitting device.

The display unit of an image pickup apparatus or an ink jet printer may have a touch panel function. The driving method for the touch panel function may be, but is not particularly limited to, an infrared method, an electrostatic capacitive method, a resistive-film method, or an electromagnetic inductive method. The display apparatus may also be used for a display unit of a multifunction printer.

The following describes a display apparatus according to the present embodiment with reference to the attached drawings.

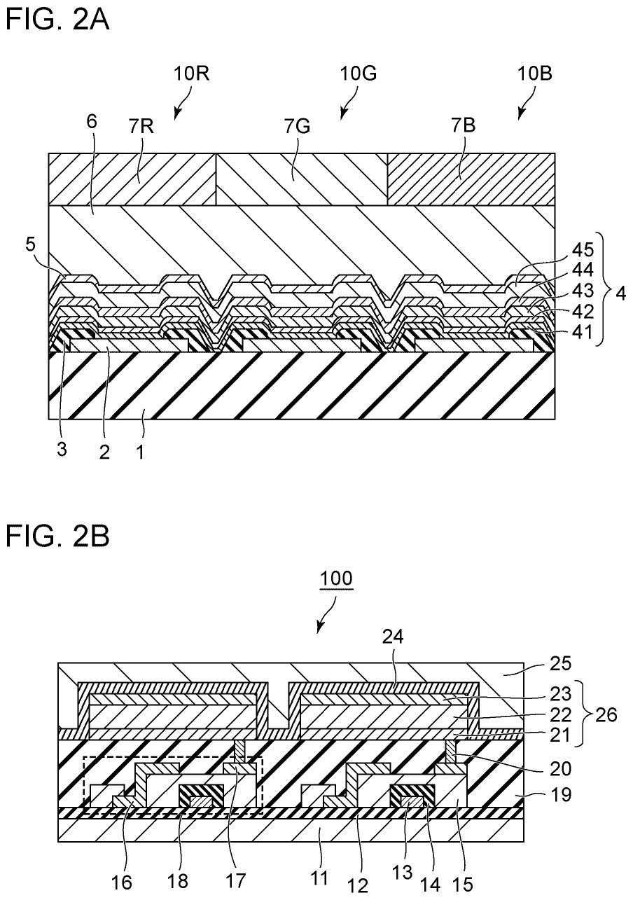

FIG. 2A is a schematic cross-sectional view illustrating an example of a display apparatus including organic light-emitting devices according to the present embodiment and transistors coupled to the organic light-emitting devices. Each of the transistors is an example of an active element. The transistors may be thin-film transistors (TFTs). The subpixels are divided into 10R, 10G, and 10B according to their light emission. The emission colors may be distinguished by the wavelength of light emitted from the light-emitting layer. Light emitted from the subpixels may be selectively transmitted or color-converted with, for example, a color filter. Each subpixel 10 includes, over an interlayer insulating layer 1, a reflective electrode serving as a first electrode 2, an insulating layer 3 covering the edge of the first electrode 2, an organic compound layer 4 covering the first electrode 2 and the insulating layer 3, a transparent electrode serving as a second electrode 5, a protective layer 6, and a color filter 7.

The transistors and capacitive elements may be disposed under or in the interlayer insulating layer 1. Each transistor may be electrically coupled to a corresponding one of the first electrodes 2 through, for example, a contact hole, which is not illustrated.

The insulating layer 3 is also referred to as a bank or pixel separation film. The insulating layer covers the edge of each first electrode 2 and surrounds the first electrode 2. Portions that are not covered with the insulating layer 3 are in contact with the organic compound layer 4 and serve as light-emitting regions.

The second electrode 5 may be a transparent electrode, a reflective electrode, or a semi-transparent electrode.

The protective layer 6 reduces the penetration of moisture into the organic compound layer 4. Although the protective layer 6 is illustrated as a single layer, the protective layer 6 may be formed of multiple layers. Each layer may be an inorganic compound layer or an organic compound layer.

The color filter 7 is separated into 7R, 7G, and 7B according to its color. The color filter 7 may be disposed on a planarization film, which is not illustrated. A resin protective layer, which is not illustrated, may be disposed on the color filter 7. The color filter 7 may also be formed on the protective layer 6. Alternatively, the color filter may be disposed on an opposite substrate, such as a glass substrate, and then bonded.

FIG. 2B is a schematic cross-sectional view illustrating an example of a display apparatus including organic light-emitting devices and transistors coupled to the organic light-emitting devices. The organic light-emitting devices 26 and thin-film transistors (TFTs) 18 as an example of transistors are provided. A substrate 11 composed of, for example, glass or silicon, is provided, and an insulating layer 12 is disposed thereon. Active elements, such as the TFTs 18, are disposed on the insulating layer 12. The gate electrode 13, the gate insulating film 14, and the semiconductor layer 15 of each of the active elements are disposed thereon. Each TFT 18 further includes a drain electrode 16 and a source electrode 17. The TFTs 18 are overlaid with an insulating film 19. Anodes 21 included in the organic light-emitting devices 26 are coupled to the source electrodes 17 through contact holes 20 provided in the insulating film 19.

The mode of electrical connection between the electrodes (anode 21 and cathode 23) included in each organic light-emitting device 26 and the electrodes (source electrode 17 and drain electrode 16) included in a corresponding one of the TFTs 18 is not limited to the mode illustrated in FIG. 2B. That is, it is sufficient that any one of the anode 21 and the cathode 23 be electrically coupled to any one of the source electrode 17 and the drain electrode 16 of the TFT 18.

In the display apparatus illustrated in FIG. 2B, each organic compound layer 22 is illustrated as a single layer; however, the organic compound layer 22 may be formed of multiple layers. A first protective layer 24 and a second protective layer 25 are disposed on the cathodes 23 in order to reduce the deterioration of the organic light-emitting devices 26.

The transistors used in the display apparatus illustrated in FIG. 2B are not limited to transistors using a single-crystal silicon wafer, but may also be thin-film transistors including active layers on the insulating surface of a substrate. Examples of the active layer include single-crystal silicon, non-single-crystal silicon materials, such as amorphous silicon and microcrystalline silicon, and non-single-crystal oxide semiconductors, such as indium-zinc oxide and indium-gallium-zinc oxide.

The transistors in the display apparatus illustrated in FIG. 2B may be formed in the substrate, such as a Si substrate. The expression “formed in the substrate” indicates that the transistors are produced by processing the substrate, such as a Si substrate. When the transistors are formed in the substrate, the substrate and the transistors can be deemed to be integrally formed.

In the organic light-emitting devices 26 according to the present embodiment, the luminance is controlled by the TFTs, which are an example of switching elements; thus, an image can be displayed at respective luminance levels by arranging multiple organic light-emitting devices 26 in the plane. The switching elements according to the present embodiment are not limited to the TFTs and may be low-temperature polysilicon transistors or active-matrix drivers formed on a substrate such as a Si substrate. The expression “on a substrate” can also be said to be “in the substrate”. Whether transistors are formed in the substrate or TFTs are used is selected in accordance with the size of a display unit. For example, when the display unit has a size of about 0.5 inches, organic light-emitting devices are preferably disposed on a Si substrate.

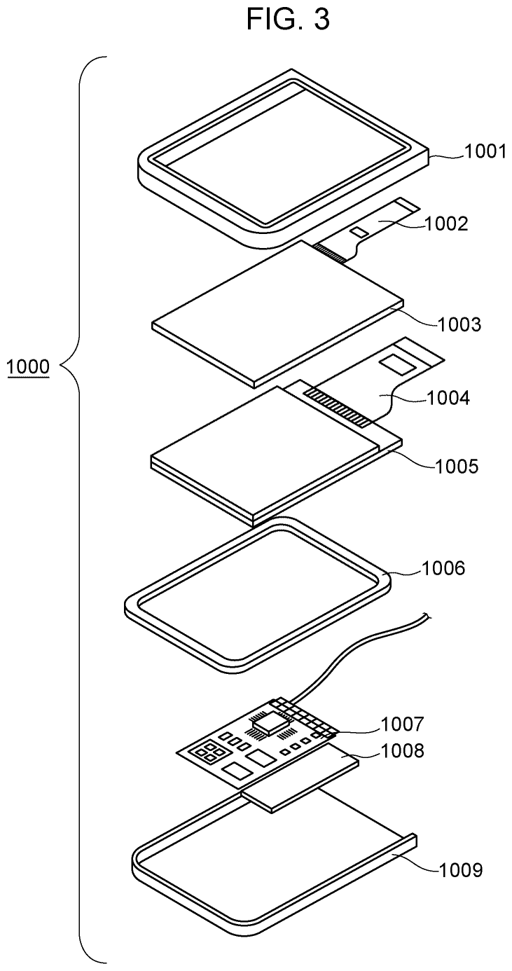

FIG. 3 is a schematic view illustrating an example of a display apparatus according to the present embodiment. A display apparatus 1000 includes, between an upper cover 1001 and a lower cover 1009, a touch panel 1003, a display panel 1005, a frame 1006, a circuit substrate 1007, and a battery 1008. The touch panel 1003 and the display panel 1005 are coupled to flexible printed circuits FPCs 1002 and 1004, respectively. The circuit substrate 1007 includes printed transistors. The battery 1008 need not be provided unless the display apparatus is a portable apparatus. The battery 1008 may be disposed at a different position even if the display apparatus is a portable apparatus.

The display apparatus according to the present embodiment may include a color filter having red, green, and blue portions. In the color filter, the red, green, and blue portions may be arranged in a delta arrangement.

The display apparatus according to the present embodiment may be used for the display unit of a portable terminal. In that case, the display apparatus may have both a display function and an operation function. Examples of the portable terminal include mobile phones, such as smartphones, tablets, and head-mounted displays.

The display apparatus according to the present embodiment may be used for a display unit of an image pickup apparatus including an optical unit including multiple lenses and an image pickup device that receives light passing through the optical unit. The image pickup apparatus may include a display unit that displays information acquired by the image pickup device. The display unit may be a display unit exposed to the outside of the image pickup apparatus or may be a display unit disposed in a finder. The image pickup apparatus may be a digital camera or a digital camcorder.

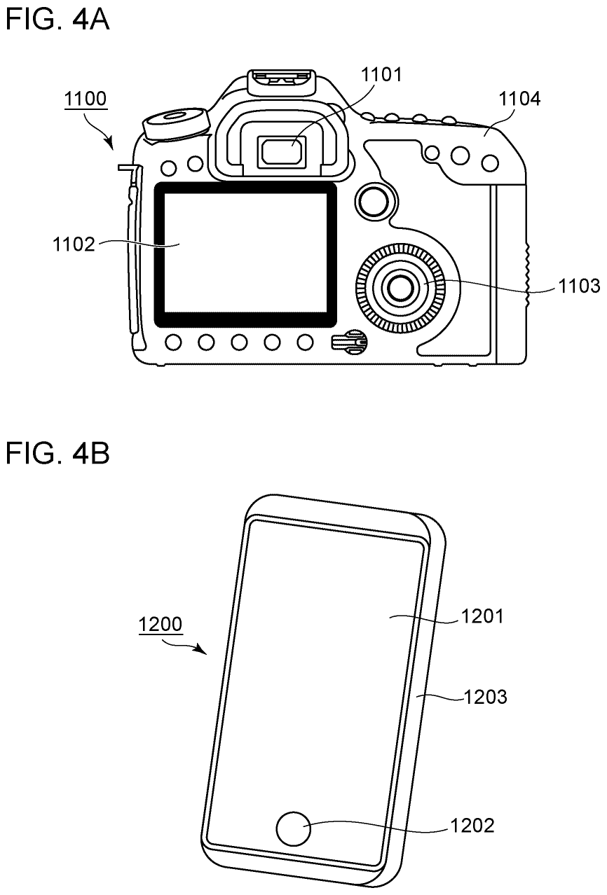

FIG. 4A is a schematic view illustrating an example of an image pickup apparatus according to the present embodiment. An image pickup apparatus 1100 may include a viewfinder 1101, a rear display 1102, an operation unit 1103, and a housing 1104. The viewfinder 1101 and the rear display 1102 may have the organic light-emitting device according to the present embodiment. In this case, the viewfinder 1101 and the rear display 1102 may display environmental information, imaging instructions, and so forth in addition to an image to be captured. The environmental information may include, for example, the intensity of external light, the direction of the external light, the moving speed of a subject, and the possibility that the subject will be shielded by an obstacle.

The timing suitable for imaging is only for a short time; thus, it is better to display the information as soon as possible. Thus, the display apparatus including the organic light-emitting device according to the present embodiment is preferably used. This is because organic light-emitting devices have a fast response time. The display apparatus including the organic light-emitting device can be used more suitably than liquid crystal display apparatuses for such apparatuses required to have a high display speed.

The image pickup apparatus 1100 may further include an optical unit, which is not illustrated. The optical unit may include a single lens or multiple lenses and is configured to form an image on an image pickup device in the housing 1104. The relative positions of the multiple lenses can be adjusted to adjust the focal point. This operation can also be performed automatically. The image pickup apparatus may also be referred to as a photoelectric conversion apparatus. Examples of an image capturing method employed in the photoelectric conversion apparatus can include a method for detecting a difference from the previous image and a method for cutting out an image from images always recorded, instead of sequentially capturing images.

FIG. 4B is a schematic view illustrating an example of an electronic apparatus according to the present embodiment. An electronic apparatus 1200 includes a display unit 1201, an operation unit 1202, and a housing 1203. The display unit 1201 may include the organic light-emitting device according to the present embodiment. The housing 1203 may accommodate a circuit, a printed circuit board including the circuit, a battery, and a communication unit. The operation unit 1202 may be a button or a touch-panel-type reactive unit. The operation unit 1202 may be a biometric recognition unit that recognizes fingerprints to perform functions, such as unlocking. An electronic apparatus including a communication unit can also be referred to as a communication apparatus. The electronic apparatus 1200 may further have a camera function by including a lens and an image pickup device. An image captured by the camera function is displayed on the display unit 1201. Examples of the electronic apparatus 1200 include smartphones and laptop computers.

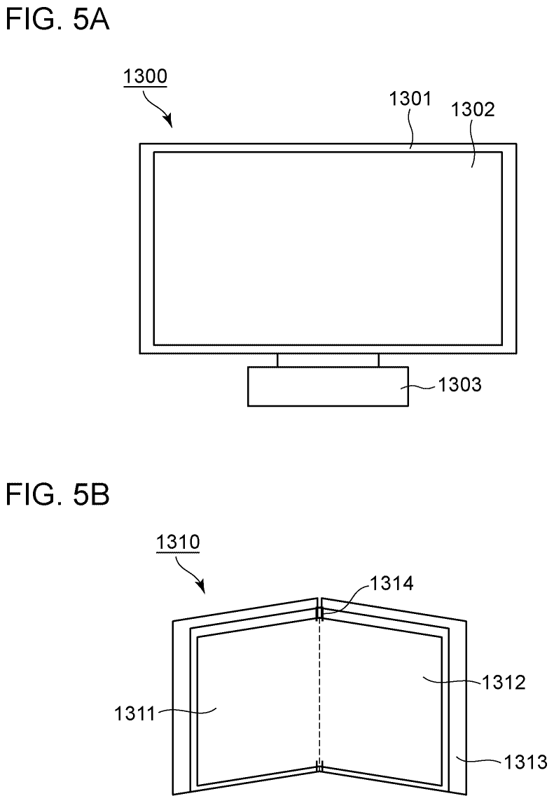

FIGS. 5A and 5B are a schematic view illustrating an example of a display apparatus according to the present embodiment. FIG. 5A illustrates a display apparatus, such as a television monitor or a PC monitor. A display apparatus 1300 includes a frame 1301 and a display unit 1302. The display unit 1302 may include the organic light-emitting device according to the present embodiment.

The display apparatus 1300 may include a base 1303 that supports the display unit 1302, if necessary. The base 1303 is not limited to a form illustrated in FIG. 5A. The lower side of the frame 1301 may also serve as a base. The frame 1301 and the display unit 1302 may be curved. The radius of curvature may be 5,000 mm or more and 6,000 mm or less.

FIG. 5B is a schematic view of another example of a display apparatus according to the present embodiment. A display apparatus 1310 illustrated in FIG. 5B can be folded and is what is called a foldable display apparatus. The display apparatus 1310 includes a first display unit 1311, a second display unit 1312, a housing 1313, and an inflection point 1314. The first display unit 1311 and the second display unit 1312 may include the organic light-emitting device according to the present embodiment. The first display unit 1311 and the second display unit 1312 may be a single, seamless display apparatus. The first display unit 1311 and the second display unit 1312 can be divided from each other at the inflection point. The first display unit 1311 and the second display unit 1312 may display different images from each other. Alternatively, a single image may be displayed in the first and second display units.

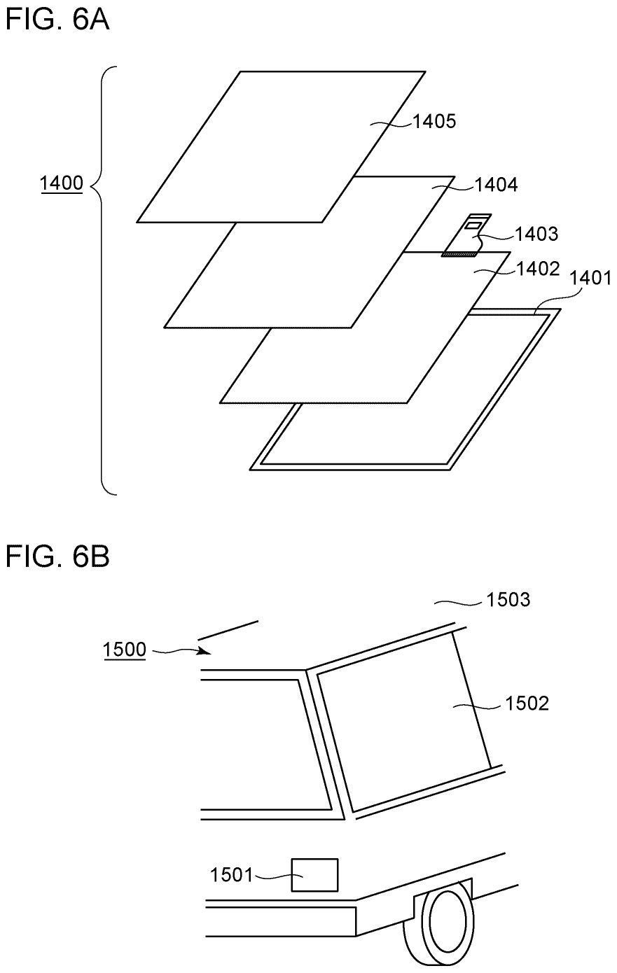

FIG. 6A is a schematic view illustrating an example of a lighting apparatus according to the present embodiment. A lighting apparatus 1400 may include a housing 1401, a light source 1402, and a circuit substrate 1403. The lighting apparatus 1400 may further include an optical filter 1404 configured to transmit light emitted from the light source 1402 and a light diffusion unit 1405. The light source 1402 includes an organic light-emitting device according to the present embodiment. The optical filter 1404 may be a filter that improves the color rendering properties of the light source. The light diffusion unit 1405 can effectively diffuse light from the light source to deliver the light to a wide range when used for illumination and so forth. The optical filter 1404 and the light diffusion unit 1405 may be disposed at the light emission side of the lighting source. A cover may be disposed at the outermost portion, as needed.

The lighting apparatus is, for example, an apparatus that lights a room. The lighting apparatus may emit light of white, neutral white, or any color from blue to red. A light control circuit that controls the light may be provided. The lighting apparatus may include the organic light-emitting device according to the present embodiment and a power supply circuit coupled to the organic light-emitting device. The power supply circuit is a circuit that converts an AC voltage into a DC voltage. The color temperature of white is 4,200 K, and the color temperature of neutral white is 5,000 K. The lighting apparatus may include a color filter.

The lighting apparatus according to the present embodiment may include a heat dissipation unit. The heat dissipation unit is configured to release the heat inside the apparatus to the outside, and materials with high thermal conductivity, such as metals and ceramics, are used.

FIG. 6B is a schematic view of an automobile as an example of a moving object according to the present embodiment. The automobile includes a tail lamp, which is an example of lighting units. An automobile 1500 includes a tail lamp 1501 and may be configured to light the tail lamp when an operation, such as braking, is performed.

The tail lamp 1501 may include an organic light-emitting device according to the present embodiment. The tail lamp 1501 may include a protective member that protects the organic light-emitting device. The protective member may be composed of any material as long as it has a certain degree of strength and is transparent. The protective member is preferably composed of, for example, polycarbonate. The polycarbonate may be mixed with, for example, a furandicarboxylic acid derivative or an acrylonitrile derivative.

The automobile 1500 may include an automobile body 1503 and windows 1502 attached thereto. The windows 1502 may be transparent displays unless they are windows used to check areas in front of and behind the automobile. The transparent displays may include the organic light-emitting devices according to the present embodiment. In this case, the constituent materials, such as the electrodes, of the organic light-emitting devices are formed of transparent members.

The moving object according to the present embodiment may be, for example, a ship, an aircraft, or a drone. The moving object may include a body and a lighting unit attached to the body. The lighting unit may emit light to indicate the position of the body. The lighting unit includes the organic light-emitting device according to the present embodiment.

The electronic apparatus or the display apparatus described above can be used for systems that can be worn as wearable devices, such as smart glasses, head-mounted displays (HMDs), and smart contact lenses. An image pickup and display apparatus used in such an application includes an image pickup apparatus that can photoelectrically convert visible light and a display apparatus that can emit visible light.

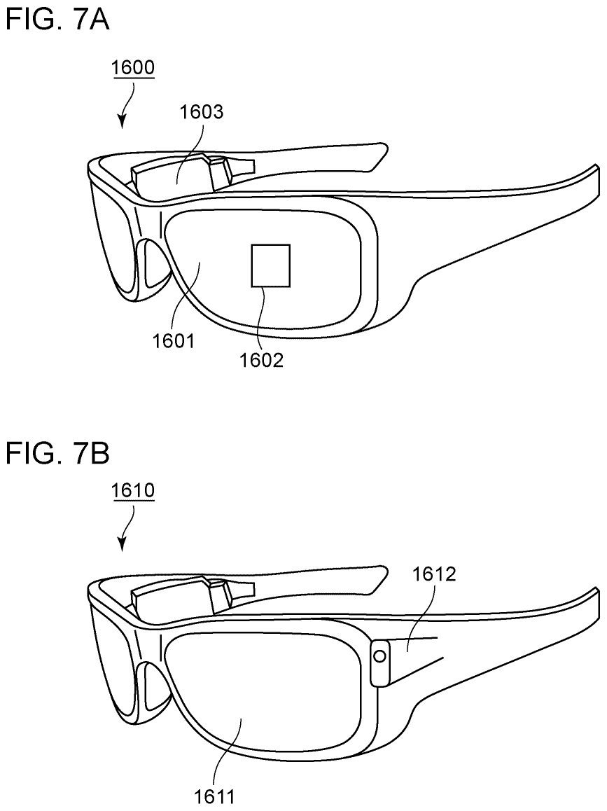

FIG. 7A is a schematic view illustrating an example of a wearable device according to the present embodiment. Glasses 1600 (smart glasses) according to an example of applications will be described with reference to FIG. 7A. The glasses 1600 include a display unit on the rear side of a lens 1601. The display unit may include an organic light-emitting device according to the present disclosure. In addition, an image pickup apparatus 1602, such as a CMOS sensor or a SPAD, may be provided on the surface side of the lens 1601.

The glasses 1600 further include a control unit 1603. The control unit 1603 functions as a power supply that supplies electric power to the image pickup apparatus 1602 and the display unit. The control unit 1603 controls the operation of the image pickup apparatus 1602 and the display unit. The lens 1601 includes an optical system for focusing light from the image pickup apparatus 1602 and the display unit.

FIG. 7B is a schematic view illustrating another example of a wearable device according to the present embodiment. Glasses 1610 (smart glasses) according to an example of applications will be described with reference to FIG. 7B. The glasses 1610 include a control unit 1612. The control unit 1612 is provided with a display apparatus including an organic light-emitting device according to the present disclosure. The control unit 1612 may further include an image pickup apparatus equivalent to the image pickup apparatus 1602. The lens 1611 is provided with an optical system for projecting light emitted from the control unit 1612, and an image is projected onto the lens 1611.

The control unit 1612 functions as a power supply that supplies electric power to the image pickup apparatus and the display apparatus and controls the operations of the image pickup apparatus and the display apparatus. The control unit may include a gaze detection unit that detects the gaze of a wearer. Infrared light may be used for gaze detection. An infrared light-emitting unit emits infrared light toward the eyeball of a user gazing at a displayed image. An image of the eyeball is captured by detecting the reflected infrared light from the eyeball with an image pickup unit having light-receiving elements. A deterioration in image quality is reduced by providing a reduction unit that reduces light from the infrared light-emitting unit to the display unit when viewed in plan.

The control unit 1612 detects the user's gaze at the displayed image from the image of the eyeball captured with the infrared light. Any known method can be used to the gaze detection using the captured image of the eyeball. As an example, a gaze detection method based on a Purkinje image of the reflection of irradiation light on a cornea can be used. More specifically, the gaze detection process is performed on the basis of a pupil-corneal reflection method. Using the pupil-corneal reflection method, the user's gaze is detected by calculating a gaze vector representing the direction (rotation angle) of the eyeball based on the image of the pupil and the Purkinje image contained in the captured image of the eyeball.

A display apparatus according to an embodiment of the present disclosure may include an image pickup apparatus including light-receiving elements, and may control an image displayed on the display apparatus based on the gaze information of the user from the image pickup apparatus. Specifically, in the display apparatus, a first field-of-view area at which the user gazes and a second field-of-view area other than the first field-of-view area are determined on the basis of the gaze information. The first field-of-view area and the second field-of-view area may be determined by the control unit of the display apparatus or may be determined by receiving those determined by an external control unit. In the display area of the display apparatus, the display resolution of the first field-of-view area may be controlled to be higher than the display resolution of the second field-of-view area. That is, the resolution of the second field-of-view area may be lower than that of the first field-of-view area.

The display area includes a first display area and a second display area different from the first display area. Based on the gaze information, an area of higher priority is determined from the first display area and the second display area. The first display area and the second display area may be determined by the control unit of the display apparatus or may be determined by receiving those determined by an external control unit. The resolution of an area of higher priority may be controlled to be higher than the resolution of an area other than the area of higher priority. In other words, the resolution of an area of a relatively low priority may be set lower.

Artificial intelligence (AI) may be used to determine the first display area or the high-priority area. The AI may be a model configured to estimate the angle of gaze from the image of the eyeball and the distance to a target object located in the gaze direction, using the image of the eyeball and the actual direction of gaze of the eyeball in the image as teaching data. The AI program may be stored in the display apparatus, the image pickup apparatus, or an external apparatus. When the AI program is stored in the external apparatus, the AI program is transmitted to the display apparatus via communications.

In the case of controlling the display based on visual detection, smart glasses that further include an image pickup apparatus that captures an external image can preferably be used. The smart glasses can display the captured external information in real time.

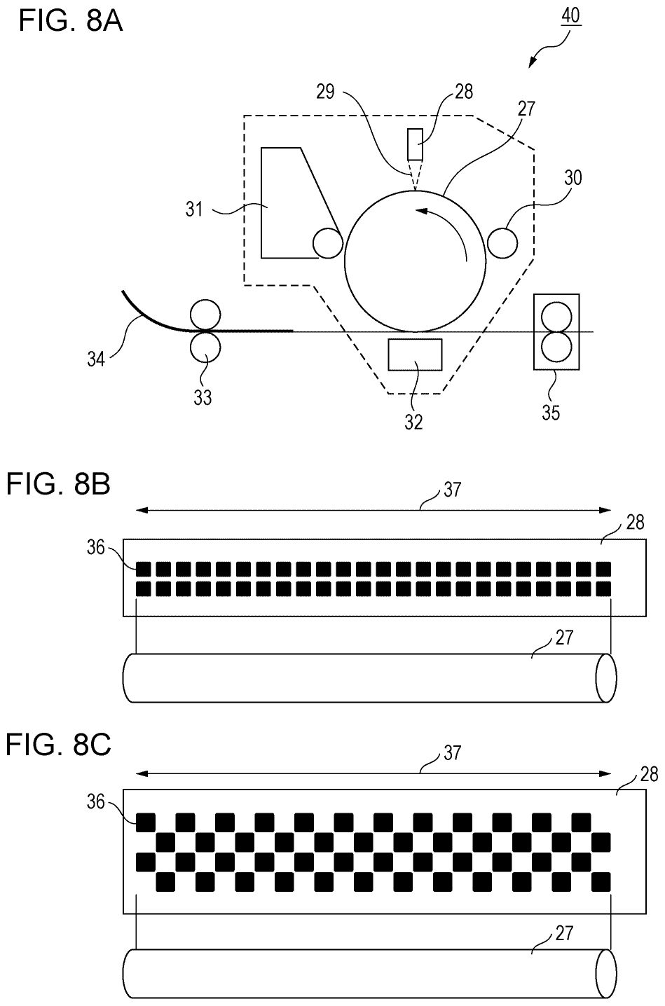

FIG. 8A is a schematic view of an example of an image-forming apparatus according to the present embodiment. An image-forming apparatus 40 is an electrophotographic image-forming apparatus and includes a photoconductor 27, an exposure light source 28, a charging unit 30, a developing unit 31, a transfer unit 32, a conveying roller 33, and a fixing unit 35. The irradiation of light 29 is performed from the exposure light source 28 to form an electrostatic latent image on the surface of the photoconductor 27. The exposure light source 28 includes the organic light-emitting device according to the present embodiment. The developing unit 31 contains, for example, a toner. The charging unit 30 charges the photoconductor 27. The transfer unit 32 transfers the developed image to a recording medium 34. The conveying roller 33 conveys the recording medium 34. The recording medium 34 is paper, for example. The fixing unit 35 fixes the image formed on the recording medium 34.

FIGS. 8B and 8C each illustrate the exposure light source 28 and are each a schematic view illustrating multiple light-emitting portions 36 arranged on a long substrate. Arrows 37 each represent the row direction in which the light-emitting portions 36 including the organic light-emitting devices are arranged. The row direction is the same as the direction of the axis about which the photoconductor 27 rotates. This direction can also be referred to as the long-axis direction of the photoconductor 27. FIG. 8B illustrates a configuration in which the light-emitting portions 36 are arranged in the long-axis direction of the photoconductor 27. FIG. 8C is different from FIG. 8B in that the light-emitting portions 36 are arranged alternately in the row direction in a first row and a second row. The first row and the second row are located at different positions in the column direction. In the first row, the multiple light-emitting portions 36 are spaced apart. The second row has the light-emitting portions 36 at positions corresponding to the positions between the light-emitting portions 36 in the first row. In other words, the multiple light-emitting portions 36 are also spaced apart in the column direction. The arrangement in FIG. 8C can be rephrased as, for example, a lattice arrangement, a staggered arrangement, or a checkered pattern.

As described above, the use of an apparatus including the organic light-emitting device according to the present embodiment enables a stable display with good image quality even over a long period of time.

### EXAMPLES

Examples are described below, but the present disclosure is not limited to the following contents.

### Example 1

In this example, a top-emission type stacked organic light-emitting device was produced in which an anode, a light-emitting unit 300, a charge generation region, a light-emitting unit 500, and a cathode were formed in this order on a substrate. An organic light-emitting device having a double-sided light-emitting structure was produced using the light-emitting unit 300 including a blue light-emitting layer and the light-emitting unit 500 including a light-emitting layer containing a green light-emitting dopant and a red light-emitting dopant.

An ITO film was formed on a glass substrate and subjected to desired patterning to form an ITO electrode (anode). At this time, the thickness of the ITO electrode was 100 nm. The substrate on which the ITO electrode had been formed in this way was used as an ITO substrate in the following steps. Next, the light-emitting unit 1, the charge generation region, and the light-emitting unit 2 given in Table 3 below were formed in this order by vacuum evaporation using resistance heating in a vacuum chamber. Here, the opposite electrode (metal electrode layer, cathode) had an electrode area of 3 mm². After the layers up to the cathode were deposited, the substrate was transferred into a glove box and encapsulated with a glass cap containing a desiccant in a nitrogen atmosphere to provide a stacked organic light-emitting device.

TABLE 1

| | | | | Thickness |
|---|---|---|---|---|
| Unit | Name of organic layer | Material | | (nm) |
| Cathode | Cathode | Mg | Ratio by weight | 10 |
| | | Ag | Mg:Ag = 50:50 | |
| | Second electron injection layer | LiF | | 1 |
| Second light- | Second electron transport layer | ET2 | | 20 |
| emitting unit | Second hole-blocking layer | ET12 | | 26 |
| | Second light-emitting layer | EM1 | Ratio by weight | 20 |
| | | GD6 | EM1:GD6:RD1 = | |
| | | RD1 | 97.6:2:0.4 | |
| | Second electron-blocking layer | HT7 | | 10 |
| Charge generation | Second hole transport layer | HT2 | | 25 |
| region | Second hole injection layer | HT16 | | 8 |
| | Intermediate layer | ETM2-1 | | 3 |
| | First electron injection layer | ET2 | Ratio by weight | 10 |
| | [n-charge generation layer] | Cs₂CO₃ | ET2:Cs₂CO₃ = 99:1 | |
| First light- | First electron transport layer | ET2 | | 20 |
| emitting unit | First hole-blocking layer | ET12 | | 33 |
| | First light-emitting layer | EM1 | Ratio by weight | 20 |
| | | BD7 | EM1:BD8 = 99:1 | |

| | | |
|---|---|---|
| First electron-blocking layer | HT7 | 10 |
| First hole transport layer | HT2 | 25 |
| First hole injection layer | HT16 | 7 |

### Comparative Example 1

As a comparative example, an organic light-emitting device was produced without an intermediate layer in the charge generation region.

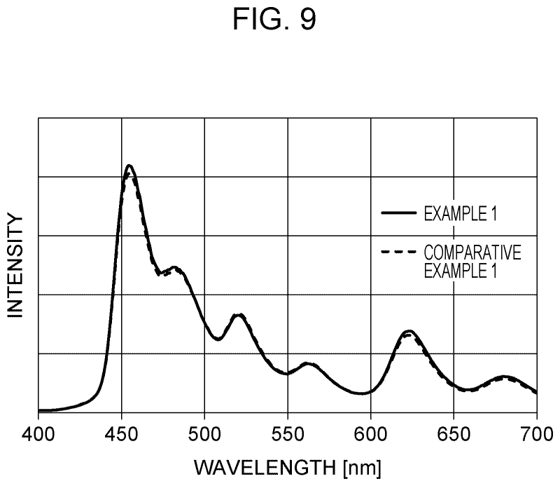

The voltage-current characteristics were measured with a Hewlett-Packard 4140B microammeter. The emission spectrum was obtained with a Topcon “SR-3”. As presented in FIG. 9, the organic light-emitting device of Example 1 and the organic light-emitting device of Comparative Example 1 exhibited similar white EL emission spectra.

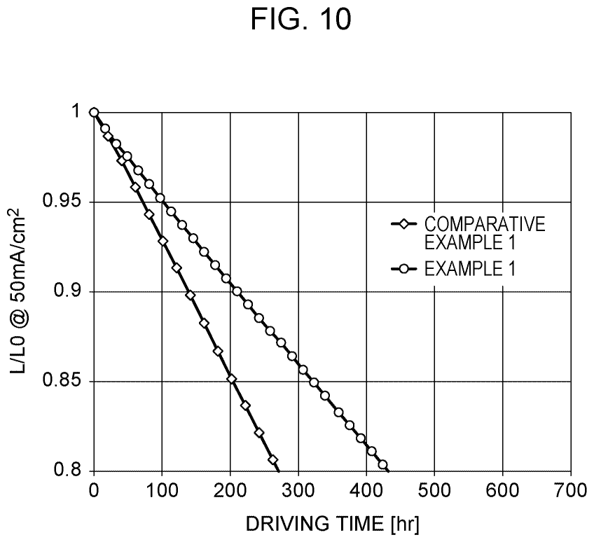

A driving test was performed on the device produced in Example 1 and the device produced in Comparative Example 1 under a constant current condition of 50 mA/cm², and LT80, defined as the time for the luminance to deteriorate by 20% from the initial luminance, was evaluated from the durability curve illustrated in FIG. 10. Table 2 summarizes the LT80 values estimated from the above.

TABLE 2

| | LT80 [hr] @50 mA/cm² |
|---|---|
| Example 1 | 432 |
| Comparative Example 1 | 271 |

From Table 2, it was found that the organic light-emitting device of Example 1 exhibited superior durability compared to the organic light-emitting device of Comparative Example 1. This is because, in the organic light-emitting device of Example 1, the diffusion of the n-type dopant toward the cathode side was inhibited by the presence of the fused polycyclic hydrocarbon compound in the intermediate layer of the charge generation region.

### Comparative Examples 2 to 4

Organic light-emitting devices were produced in the same manner as in Example 1, except that the compounds used for the intermediate layers were changed to those given in the table below. The LT80 was then evaluated.

TABLE 3

| | Compound in | LT80 [hr] |
|---|---|---|
| | intermediate layer | @50 mA/cm² |
| Comparative Example 2 | ET1 | 280 |
| Comparative Example 3 | ET4 | 260 |
| Comparative Example 4 | HT20 | 300 |

Table 3 indicates that all the organic light-emitting devices of Comparative Examples 2 to 4 had lower LT80 values than that of Example 1. This is because in the organic light-emitting devices of Comparative Examples 2 to 4, the diffusion of the n-type dopant into the light-emitting layers was not sufficiently inhibited due to the use of highly polar compounds in the intermediate layers.

### Examples 2 to 4

Organic light-emitting devices were produced in the same manner as in Example 1, except that the compounds used for the intermediate layers were changed to those given in the table below. The LT80 was then evaluated.

TABLE 4

| | Compound in | LT80 [hr] |
|---|---|---|
| | intermediate layer | @50 mA/cm² |
| Example 2 | ETM2-4 | 370 |
| Example 3 | ETM2-6 | 420 |
| Example 4 | ETM2-19 | 400 |

From Table 4, it was found that the organic light-emitting devices of Examples 2 to 4 also exhibited excellent durability, similar to that of the organic light-emitting device in Example 1. This is because, in the organic light-emitting device of Example 1, the diffusion of the n-type dopant toward the cathode side was inhibited by the presence of the fused polycyclic hydrocarbon compound in the intermediate layer of the charge generation region.

### Examples 5 to 8

Organic light-emitting devices were produced in the same manner as in Example 1, except that the compounds used for the intermediate layers were changed to those given in the table below. The LT80 was then evaluated.

TABLE 5

| | | Thickness of | LT80 |
|---|---|---|---|
| | Compound in | intermediate | [hr] @50 |
| | intermediate layer | layer (nm) | mA/cm² |
| Example 5 | ETM2-1 | 1 | 330 |
| Example 1 | ETM2-1 | 3 | 432 |
| Example 6 | ETM2-1 | 5 | 410 |
| Example 7 | ETM2-19 | 1 | 330 |
| Example 4 | ETM2-19 | 3 | 400 |
| Example 8 | ETM2-19 | 5 | 390 |

From Table 5, it was found that when the thickness of each intermediate layer was 3 nm, the organic light-emitting device exhibited superior durability. This is thought to be because when the thickness is large, the intermediate layer exhibits a low electron injection ability. The organic light-emitting devices each including the intermediate layer composed of EMT2-1 exhibited superior LT80 values. This is thought to be due to the fact that ETM2-1 has a highly planar skeleton and thus facilitates intermolecular stacking.

### Example 9

An organic light-emitting device having the following device configuration was produced. The LT80 was then evaluated.

TABLE 6

| | | | | Thickness |
|---|---|---|---|---|
| Unit | Name of organic layer | Material | | (nm) |
| Cathode | Cathode | Ma | Ratio by weight | 10 |
| | | Ag | Mg:Ag = 50:50 | |
| | Second electron injection layer | LiF | | 1 |
| Second light- | Second electron transport layer | ET2 | | 20 |
| emitting unit | Second hole-blocking layer | ET12 | | 26 |
| | Second light-emitting layer | EM1 | Ratio by weight | |
| | | GD6 | EM1:GD6:RD1 = | 20 |
| | | RD1 | 97.6:2:0.4 | |
| | Second electron-blocking layer | HT7 | | 10 |
| Charge | Second hole transport layer | HT2 | | 25 |
| generation | Second hole injection layer | HT16 | | 8 |
| region | Intermediate layer | ETM2-1 | | 3 |
| | First electron injection layer | ET2 | Ratio by weight | 10 |
| | [n-charge generation layer] | Cs₂CO₃ | ET2:Cs₂CO₃ = 99:1 | |
| First Light- | First electron transport layer | ETM2-1 | ET2:ETM2-1 = 90:10 | 20 |
| emitting unit | | ET2 | | |
| | First hole-blocking layer | ET12 | | 33 |
| | First light-emitting layer | EM1 | Ratio by weight | 20 |
| | | BD7 | EM1:BD8 = 99:1 | |

| | | |
|---|---|---|
| First electron-blocking layer | HT7 | 10 |
| First hole transport layer | HT2 | 25 |
| First hole injection layer | HT16 | 7 |

### Examples 10 to 16

Organic light-emitting devices were produced in the same manner as in Example 9, except that the compounds used for the first electron transport layers were changed to those given in the table below. The LT80 was then evaluated.

TABLE 7

| | | | Concentration of | | |
|---|---|---|---|---|---|
| | | Fused hydrocarbon | fused hydrocarbon | | |
| | Compound in | compound in first | compound in first | | LT80 |
| | intermediate | electron transport | electron transport | | [hr] @50 |
| | layer | layer | layer | | mA/cm² |
| Example 9 | ETM2-1 | ETM2-1 | 10 | wt % | 450 |
| Example 10 | ETM2-1 | ETM2-1 | 30 | wt % | 560 |
| Example 11 | ETM2-1 | ETM2-1 | 50 | wt % | 550 |
| Example 12 | ETM2-1 | ETM2-1 | 100 | wt % | 490 |
| Example 13 | ETM2-1 | ETM2-6 | 10 | wt % | 480 |
| Example 14 | ETM2-1 | ETM2-6 | 30 | wt % | 550 |
| Example 15 | ETM2-1 | ETM2-6 | 50 | wt % | 570 |
| Example 16 | ETM2-1 | ETM2-6 | 100 | wt % | 500 |

From Table 7, it was found that the organic light-emitting devices of Examples 9 to 16 exhibited superior durability because the first electron transport layers contained the fused polycyclic hydrocarbon compounds, thereby inhibiting the diffusion of the n-type dopant.

### Examples 17 to 28

Organic light-emitting devices having the following device configuration were produced. The LT80 was then evaluated.

TABLE 8

| | | | | Thickness |
|---|---|---|---|---|
| Unit | Name of organic layer | Material | | (nm) |
| Cathode | Cathode | Ma | Ratio by weight | 10 |
| | | Ag | Mg:Ag = 50:50 | |
| | Second electron injection layer | LiF | | 1 |
| Second light- | Second electron transport layer | ET2 | | 20 |
| emitting unit | Second hole-blocking layer | ET12 | | 26 |
| | Second light-emitting layer | EM1 | Ratio by weight | 20 |
| | | GD6 | EM1:GD6:RD1 = | |
| | | RD1 | 97.6:2:0.4 | |
| | Second electron-blocking layer | HT7 | | 10 |
| Charge | Second hole transport layer | HT2 | | 25 |
| generation | Second hole injection layer | HT16 | | 8 |
| region | Intermediate layer | ETM2-1 | | 3 |
| | First electron injection layer | ET2 | Ratio by weight | 10 |
| | [n-charge generation layer] | ETM2-1 | ET2:ETM2-1:Cs₂CO₃ = | |
| | | Cs₂CO₃ | 69.3:29.7:1 | |
| First Light- | First electron transport layer | ETM2-1 | ET2:ETM2-1 = 90:10 | 20 |
| emitting unit | | ET2 | | |
| | First hole-blocking layer | ET12 | | 33 |
| | First light-emitting layer | EM1 | Ratio by weight | 20 |
| | | BD7 | EM1:BD8 = 99:1 | |

| | | |
|---|---|---|
| First electron-blocking layer | HT7 | 10 |
| First hole transport layer | HT2 | 25 |
| First hole injection layer | HT16 | 7 |

Organic light-emitting devices were produced in the same manner as in Example 1, except that the compounds used for the first electron transport layers were changed to those given in the table below. The LT80 was then evaluated.

TABLE 9

| | | | Concentration | | | | | |
|---|---|---|---|---|---|---|---|---|
| | | Fused | of fused | | Fused | Concentration | | |
| | Compound | hydrocarbon | hydrocarbon | | hydrocarbon | of fused | | |
| | in | compound in | compound in | | compound | hydrocarbon | | |
| | intermediate | first electron | first electron | | in nCGL | compound in | | LT80 [hr] |
| | layer | transport layer | transport layer | | layer | nCGL layer | | @50 mA/cm² |
| Example 17 | ETM2-1 | ETM2-1 | 30 | wt % | ETM2-1 | 10 | wt % | 590 |
| Example 18 | ETM2-1 | ETM2-1 | 30 | wt % | ETM2-1 | 30 | wt % | 660 |
| Example 19 | ETM2-1 | ETM2-1 | 30 | wt % | ETM2-1 | 50 | wt % | 640 |
| Example 20 | ETM2-1 | ETM2-1 | 100 | wt % | ETM2-1 | 10 | wt % | 510 |
| Example 21 | ETM2-1 | ETM2-1 | 100 | wt % | ETM2-1 | 30 | wt % | 520 |
| Example 22 | ETM2-1 | ETM2-1 | 100 | wt % | ETM2-1 | 50 | wt % | 540 |
| Example 23 | ETM2-1 | ETM2-6 | 30 | wt % | ETM2-19 | 10 | wt % | 590 |
| Example 24 | ETM2-1 | ETM2-6 | 30 | wt % | ETM2-19 | 30 | wt % | 620 |
| Example 25 | ETM2-1 | ETM2-6 | 30 | wt % | ETM2-19 | 50 | wt % | 630 |
| Example 26 | ETM2-1 | ETM2-6 | 100 | wt % | ETM2-19 | 10 | wt % | 540 |
| Example 27 | ETM2-1 | ETM2-6 | 100 | wt % | ETM2-19 | 30 | wt % | 600 |
| Example 28 | ETM2-1 | ETM2-6 | 100 | wt % | ETM2-19 | 50 | wt % | 580 |

From Table 9, it was found that when the n-type charge generation layers and the first electron transport layers containing the fused polycyclic hydrocarbon compounds exhibited superior LT80 values. This is because the diffusion of the n-type dopant can be inhibited by decreasing the polarity of the n-type charge generation layers and the first electron transport layers.

### Examples 29 to 31 and Comparative Examples 5 and 6

Next, the use of different n-dopants was investigated.

Devices were produced in the same manner as in Example 1, except that ETM2-6 was used for the intermediate layers and Cs (cesium), Li (lithium), and Yb (ytterbium) were used as n-type dopants. The LT80 was then evaluated. For comparison, devices were produced in the same manner as in Comparative Example 1, except that Cs, Li, and Yb were used as n-type dopants. The LT80 was then evaluated.

TABLE 10

| | | Compound in | LT80 |
|---|---|---|---|
| | | intermediate | [hr] @50 |
| | n-Dopant | layer | mA/cm² |
| Example 29 | Cs | ETM2-6 | 440 |
| Comparative Example 1 | Cs | None | 271 |
| Example 30 | Li | ETM2-6 | 465 |
| Comparative Example 5 | Li | None | 290 |
| Example 31 | Yb | ETM2-6 | 380 |
| Comparative Example 6 | Yb | None | 190 |

From Table 10, it was found that each of the organic light-emitting devices according to the present disclosure exhibited excellent durability, regardless of the type of n-type dopant.

### Examples 32 to 61

Organic light-emitting devices were produced in the same manner as in Example 1, except that the compounds used for the intermediate layers were changed to those given in the table below. The LT80 was then evaluated. Each value in parentheses in Table 11 indicates the amount of the corresponding compound contained in the corresponding intermediate layer. For example, (25%) indicates 25% by mass.

TABLE 11

| | | | LT80 [hr] |
|---|---|---|---|
| | Composition of intermediate layer | | @50 mA/cm² |
| Example 32 | ETM2-1 (25%) | HT20 (75%) | 330 |
| Example 33 | ETM2-1 (50%) | HT20 (50%) | 375 |
| Example 34 | ETM2-1 (75%) | HT20 (25%) | 400 |
| Example 35 | ETM2-1 (25%) | ET2 (75%) | 330 |
| Example 36 | ETM2-1 (50%) | ET2 (50%) | 380 |
| Example 37 | ETM2-1 (75%) | ET2 (25%) | 410 |
| Example 38 | ETM2-1 (25%) | ET7 (75%) | 340 |
| Example 39 | ETM2-1 (50%) | ET7 (50%) | 420 |
| Example 40 | ETM2-1 (75%) | ET7 (25%) | 430 |
| Example 41 | ETM2-1 (25%) | ET19 (75%) | 330 |
| Example 42 | ETM2-1 (50%) | ET19 (50%) | 350 |
| Example 43 | ETM2-1 (75%) | ET19 (25%) | 400 |
| Example 44 | ETM2-4 (25%) | HT20 (75%) | 315 |
| Example 45 | ETM2-4 (50%) | HT20 (50%) | 325 |
| Example 46 | ETM2-4 (75%) | HT20 (25%) | 350 |
| Example 47 | ETM2-4 (25%) | ET7 (75%) | 310 |
| Example 48 | ETM2-4 (50%) | ET7 (50%) | 355 |
| Example 49 | ETM2-4 (75%) | ET7 (25%) | 365 |
| Example 50 | ETM2-6 (25%) | ET7 (75%) | 330 |
| Example 51 | ETM2-6 (50%) | ET7 (50%) | 410 |
| Example 52 | ETM2-6 (75%) | ET7 (25%) | 420 |
| Example 53 | ETM2-19 (25%) | ET7 (75%) | 310 |
| Example 54 | ETM2-19 (50%) | ET7 (50%) | 390 |
| Example 55 | ETM2-19 (75%) | ET7 (25%) | 400 |
| Example 56 | ETM2-19 (25%) | ET2 (75%) | 330 |
| Example 57 | ETM2-19 (50%) | ET2 (50%) | 365 |
| Example 58 | ETM2-19 (75%) | ET2 (25%) | 385 |
| Example 59 | ETM2-19 (25%) | ET19 (75%) | 330 |
| Example 60 | ETM2-19 (50%) | ET19 (50%) | 350 |
| Example 61 | ETM2-19 (75%) | ET19 (25%) | 380 |

From Table 11, it was found that even when the intermediate layer contained the compound other than the fused polycyclic hydrocarbon compound, excellent durability was exhibited. It was found that each of the organic light-emitting devices according to Examples 32 to 61 exhibited better durability as the fused polycyclic hydrocarbon compound content increased. It was found that when the intermediate layer contained the compound other than the fused polycyclic hydrocarbon compound, the device exhibited outstanding durability when the compound was a compound having multiple phenanthroline skeletons, such as ET7.

### Examples 62 to 67

Organic light-emitting devices were produced in the same manner as in Example 1, except that the compounds used for the intermediate layers were changed to those given in the table below. The LT80 was then evaluated. Each value in parentheses in Table 12 indicates the amount of the corresponding compound contained in the corresponding intermediate layer. For example, the expression (25%) indicates 25% by mass.

TABLE 12

| | | | LT80 [hr] |
|---|---|---|---|
| | Composition of intermediate layer | | @50 mA/cm² |
| Example 62 | ETM2-1 (25%) | ETM2-19 (75%) | 410 |
| Example 63 | ETM2-1 (50%) | ETM2-19 (50%) | 420 |
| Example 64 | ETM2-1 (75%) | ETM2-19 (25%) | 430 |
| Example 65 | ETM2-6 (25%) | ETM2-19 (75%) | 410 |
| Example 66 | ETM2-6 (50%) | ETM2-19 (50%) | 415 |
| Example 67 | ETM2-6 (75%) | ETM2-19 (25%) | 420 |

From Table 12, it was found that each of the organic light-emitting devices of Examples 62 to 67 exhibited excellent durability even when the intermediate layer contained two fused polycyclic hydrocarbon compounds.

As described above, in the organic light-emitting device according to the present disclosure, the intermediate layer of the charge generation region contains the fused polycyclic hydrocarbon compound, and therefore, the diffusion of the n-type dopant can be inhibited. As a result, the organic light-emitting device according to the present disclosure has excellent durability. Furthermore, since at least one of the electron transport layer and the charge generation layer contains a fused polycyclic hydrocarbon compound, the organic light-emitting device having superior durability can be provided.

According to the present disclosure, the organic light-emitting device having excellent durability can be provided.

The present disclosure may have the following configurations.

### Configuration 1

An organic light-emitting device includes, in this order, a first electrode, a first light-emitting layer, a charge transport layer, a charge generation region including a charge generation layer and an intermediate layer, a second light-emitting layer, and a second electrode, in which the charge generation layer contains a metal atom, the intermediate layer is disposed between the charge generation layer and the second light-emitting layer, and the intermediate layer contains a fused polycyclic hydrocarbon compound.

### Configuration 2

In the organic light-emitting device described in configuration 1, the intermediate layer is adjacent to the charge generation layer.

### Configuration 3

In the organic light-emitting device described in configuration 1 or 2, the charge transport layer is adjacent to the charge generation layer.

### Configuration 4

In the organic light-emitting device described in any one of configurations 1 to 3, the charge generation layer contains a fused polycyclic hydrocarbon compound.

### Configuration 5

In the organic light-emitting device described in any one of configurations 1 to 4, the fused polycyclic hydrocarbon compound has a skeleton having 10 or more and 30 or less carbon atoms.

### Configuration 6

In the organic light-emitting device described in any one of configurations 1 to 5, the fused polycyclic hydrocarbon compound contains naphthalene, fluorene, phenanthrene, triphenylene, anthracene, pyrene, chrysene, perylene, fluoranthene, or derivatives thereof.

### Configuration 7

In the organic light-emitting device described in any one of configurations 1 to 6, the fused polycyclic hydrocarbon compound contains a skeleton containing four or more rings.

### Configuration 8

In the organic light-emitting device described in any one of configurations 1 to 7, the fused polycyclic hydrocarbon compound contains a pyrene skeleton and a fluorene skeleton.

### Configuration 9

In the organic light-emitting device described in any one of configurations 1 to 8, the charge transport layer is an electron transport layer containing a fused polycyclic hydrocarbon compound, and the fused polycyclic hydrocarbon compound contained in the electron transport layer is identical to the fused polycyclic hydrocarbon compound contained in the intermediate layer.

### Configuration 10

In the organic light-emitting device described in configuration 9, the charge generation layer contains a fused polycyclic hydrocarbon compound, and the fused polycyclic hydrocarbon compound contained in the charge generation layer, the fused polycyclic hydrocarbon compound contained in the electron transport layer, and the fused polycyclic hydrocarbon compound contained in the intermediate layer are identical.

### Configuration 11

In the organic light-emitting device described in any one of configurations 1 to 10, the charge generation layer is an n-type charge generation layer, and the metal atom is an alkali metal atom or an alkaline-earth metal atom.

### Configuration 12

In the organic light-emitting device described in configuration 11, the metal atom is a lithium atom.

### Configuration 13

A display apparatus includes multiple pixels, at least one of the multiple pixels including the organic light-emitting device described in any one of configurations 1 to 12 and a transistor coupled to the organic light-emitting device.

### Configuration 14

A display apparatus includes a display unit including the organic light-emitting device described in any one of configurations 1 to 12, and a housing provided with the display unit.

### Configuration 15

A photoelectric conversion apparatus includes an image pickup device configured to receive light, and a display unit configured to display an image captured by the image pickup device,
in which the display unit includes the organic light-emitting device according to any one of configurations 1 to 12.

### Configuration 16

An electronic apparatus includes a display unit including the organic light-emitting device described in any one of configurations 1 to 12, a housing provided with the display unit, and a communication unit disposed in the housing and configured to communicate with an outside.

### Configuration 17

A wearable device includes a display unit including the organic light-emitting device described in any one of configurations 1 to 12, an optical system configured to focus light from the display unit, and a control unit configured to control display of the display unit.

### Configuration 18

A lighting apparatus includes a light source including the organic light-emitting device described in any one of configurations 1 to 12, and a housing provided with the light source.

### Configuration 19

A moving object includes a lighting unit including the organic light-emitting device described in any one of configurations 1 to 12, and a body provided with the lighting unit.

### Configuration 20

An image-forming apparatus includes a photoconductor, and an exposure light source configured to expose the photoconductor,
in which the exposure light source includes the organic light-emitting device according to any one of claims 1 to 12.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

1. An organic light-emitting device, comprising, in this order, a first electrode, a first light-emitting layer, a charge transport layer, a charge generation region including a charge generation layer and an intermediate layer, a second light-emitting layer, and a second electrode,
wherein the charge generation layer contains a metal atom,
the intermediate layer is disposed between the charge generation layer and the second light-emitting layer, and
the intermediate layer contains a fused polycyclic hydrocarbon compound that is composed of a hydrocarbon.

2. The organic light-emitting device according to claim 1, wherein the intermediate layer is adjacent to the charge generation layer.

3. The organic light-emitting device according to claim 1, wherein the charge transport layer is adjacent to the charge generation layer.

4. The organic light-emitting device according to claim 1, wherein the charge generation layer contains a fused polycyclic hydrocarbon compound.

5. The organic light-emitting device according to claim 1, wherein the fused polycyclic hydrocarbon compound has a skeleton having 10 or more and 30 or less carbon atoms.

6. The organic light-emitting device according to claim 1, wherein the fused polycyclic hydrocarbon compound contains naphthalene, fluorene, phenanthrene, triphenylene, anthracene, pyrene, chrysene, perylene, fluoranthene, or derivatives thereof.

7. The organic light-emitting device according to claim 1, wherein the fused polycyclic hydrocarbon compound contains a skeleton containing four or more rings.

8. The organic light-emitting device according to claim 1, wherein the fused polycyclic hydrocarbon compound contains a pyrene skeleton and a fluorene skeleton.

9. The organic light-emitting device according to claim 1, wherein the charge transport layer is an electron transport layer containing a fused polycyclic hydrocarbon compound, and the fused polycyclic hydrocarbon compound contained in the electron transport layer is identical to the fused polycyclic hydrocarbon compound contained in the intermediate layer.

10. The organic light-emitting device according to claim 9, wherein the charge generation layer contains a fused polycyclic hydrocarbon compound, and the fused polycyclic hydrocarbon compound contained in the charge generation layer, the fused polycyclic hydrocarbon compound contained in the electron transport layer, and the fused polycyclic hydrocarbon compound contained in the intermediate layer are identical.

11. The organic light-emitting device according to claim 1, wherein the charge generation layer is an n-type charge generation layer, and the metal atom is an alkali metal atom or an alkaline-earth metal atom.

12. The organic light-emitting device according to claim 11, wherein the metal atom is a lithium atom.

13. A display apparatus, comprising multiple pixels, at least one of the multiple pixels including the organic light-emitting device according to claim 1 and a transistor coupled to the organic light-emitting device.

14. A display apparatus, comprising a display unit including the organic light-emitting device according to claim 1, and a housing provided with the display unit.

15. A photoelectric conversion apparatus, comprising an image pickup device configured to receive light, and a display unit configured to display an image captured by the image pickup device,
wherein the display unit includes the organic light-emitting device according to claim 1.

16. An electronic apparatus, comprising a display unit including the organic light-emitting device according to claim 1, a housing provided with the display unit, and a communication unit disposed in the housing and configured to communicate with an outside.

17. A wearable device, comprising a display unit including the organic light-emitting device according to claim 1, an optical system configured to focus light from the display unit, and a control unit configured to control display of the display unit.

18. A lighting apparatus, comprising a light source including the organic light-emitting device according to claim 1, and a housing provided with the light source.

19. A moving object, comprising a lighting unit including the organic light-emitting device according to claim 1, and a body provided with the lighting unit.

20. An image-forming apparatus, comprising a photoconductor, and an exposure light source configured to expose the photoconductor,
wherein the exposure light source includes the organic light-emitting device according to claim 1.
